(19) United States
(12) Patent Application Publication
(10) Pub. No.: US 2015/0179962 A1
(43) Pub. Date: Jun. 25, 2015

(54) SILANE COMPOUND AND ORGANIC ELECTROLUMINESCENCE DEVICE

(71) Applicant: SAMSUNG DISPLAY CO., LTD., Yongin-City (KR)

(72) Inventor: Ichinori TAKADA, Yokohama (JP)

(21) Appl. No.: 14/568,702

(22) Filed: Dec. 12, 2014

(30) Foreign Application Priority Data
Dec. 19, 2013 (JP) 2013-262276

(51) Int. Cl. H01L 51/00; H01L 51/50

(52) U.S. Cl. CPC H01L 51/0094; H01L 51/5012

(57) ABSTRACT

A silane compound is represented by the following Formula 1.

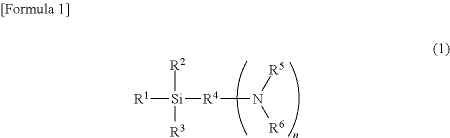

where R¹ to R⁶ are as defined in the specification.

### CROSS-REFERENCE TO RELATED APPLICATION

Japanese Patent Application No. 2013-262276, filed on Dec. 19, 2013, in the Japanese Patent Office, and entitled: “Silane Compound and Organic Electroluminescence Device,” is incorporated by reference herein in its entirety.

### BACKGROUND

1. Field

Embodiments relate to a silane compound and an organic electroluminescence device.

2. Description of the Related Art

In recent years, organic electroluminescence (EL) displays that are one type of image displays have been actively developed. Unlike a liquid crystal display and the like, the organic EL display is so-called a self-luminescent display that recombines holes and electrons injected from an anode and a cathode in an emission layer to thus emit lights from a light-emitting material including an organic compound of the emission layer, thereby performing display.

### SUMMARY

Embodiments are directed to CLAIM LANGUAGE TO BE ADDED

The present disclosure provides a silane compound and an organic EL device using the silane compound, which may have increased emission efficiency and life in consideration of the above-described defects.

Embodiments provide silane compounds represented by following Formula 1.

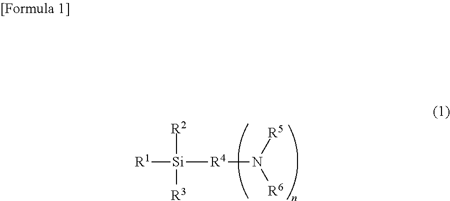

where all of R¹ to R⁶ are unsubstituted, or a monovalent or a divalent substituent derived from an aromatic hydrocarbon or a heteroaromatic ring having 5 to 30 carbon atoms including an alkyl group having at most 12 carbon atoms in at least one of R¹ to R⁶,

the carbon number of R¹ is greater than the carbon number of R⁴ by at least 4,

the carbon number of R² and R³ is at most 12,

the carbon number of R⁵ and R⁶ is at most 18,

n is an integer from 1 to 3, and

conditions of the following (1) to (3) are satisfied,

(1) the number of substituent of an alkyl group substituted in R¹ to R⁵ does not exceed the number of hydrogen atom of R¹ to R⁵,

(2) the carbon number of R¹ to R⁶ is obtained by subtracting the carbon number in a substituted alkyl group of R¹ to R⁶, and

(3) the monovalent group or the divalent group is not generated from the substituted alkyl group of R¹ to R⁵.

In the silane compound, the size of four substituents combined with a silicon atom has a certain relation, and the localization of a highest occupied molecular orbital (HOMO) and a lowest unoccupied molecular orbital (LUMO) may be possible. By using the silane compound in an organic EL device, the emission efficiency and the life of the organic EL device may be improved.

In some embodiments, R¹ to R⁶ may be a monovalent or a divalent substituent derived from a heteroaromatic group, benzene, naphthalene, anthracene, phenanthrene, carbazole, dibenzofuran, dibenzothiophene, indole, benzofuran, benzothiophene, or an aromatic hydrocarbon produced by connecting thereof to each other.

By using the silane compound having the above-described substituents in an organic EL device, the emission efficiency or the life of the organic EL device may be improved further.

In other embodiments, R¹ may be (R⁷)ᵢ, where R⁷ is a benzene or naphthylene moiety. R⁴ may be (R⁷)ⱼ, where R⁷ is a benzene or naphthylene moiety. i may be greater than j.

By using the silane compound having the above-described substituents in an organic EL device, the emission efficiency or the life of the organic EL device may be improved further.

In still other embodiments, R¹, R², and R³ may be the same.

By using the silane compound having the above-described substituents in an organic EL device, the emission efficiency or the life of the organic EL device may be improved further.

In even other embodiments, the silane compound may be at least one selected from the following Compounds 1 to 24:

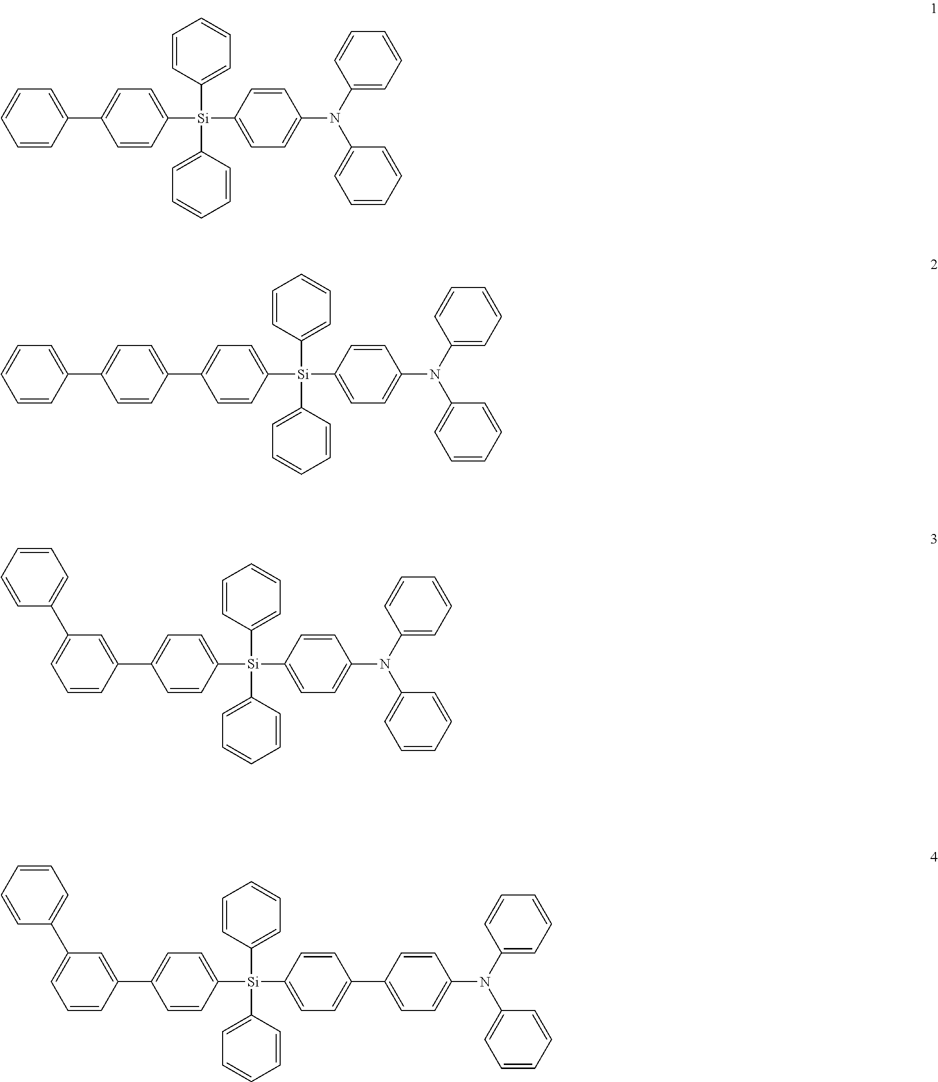 [SMILES: c1ccc(-c2ccc([Si](c3ccccc3)(c3ccccc3)c3ccc(N(c4ccccc4)c4ccccc4)cc3)cc2)cc1 ; c1ccc(-c2ccc(-c3ccc([Si](c4ccccc4)(c4ccccc4)c4ccc(N(c5ccccc5)c5ccccc5)cc4)cc3)cc2)cc1 ; c1ccc(-c2cccc(-c3ccc([Si](c4ccccc4)(c4ccccc4)c4ccc(N(c5ccccc5)c5ccccc5)cc4)cc3)c2)cc1 ; c1ccc(-c2cccc(-c3ccc([Si](c4ccccc4)(c4ccccc4)c4ccc(-c5ccc(N(c6ccccc6)c6ccccc6)cc5)cc4)cc3)c2)cc1]

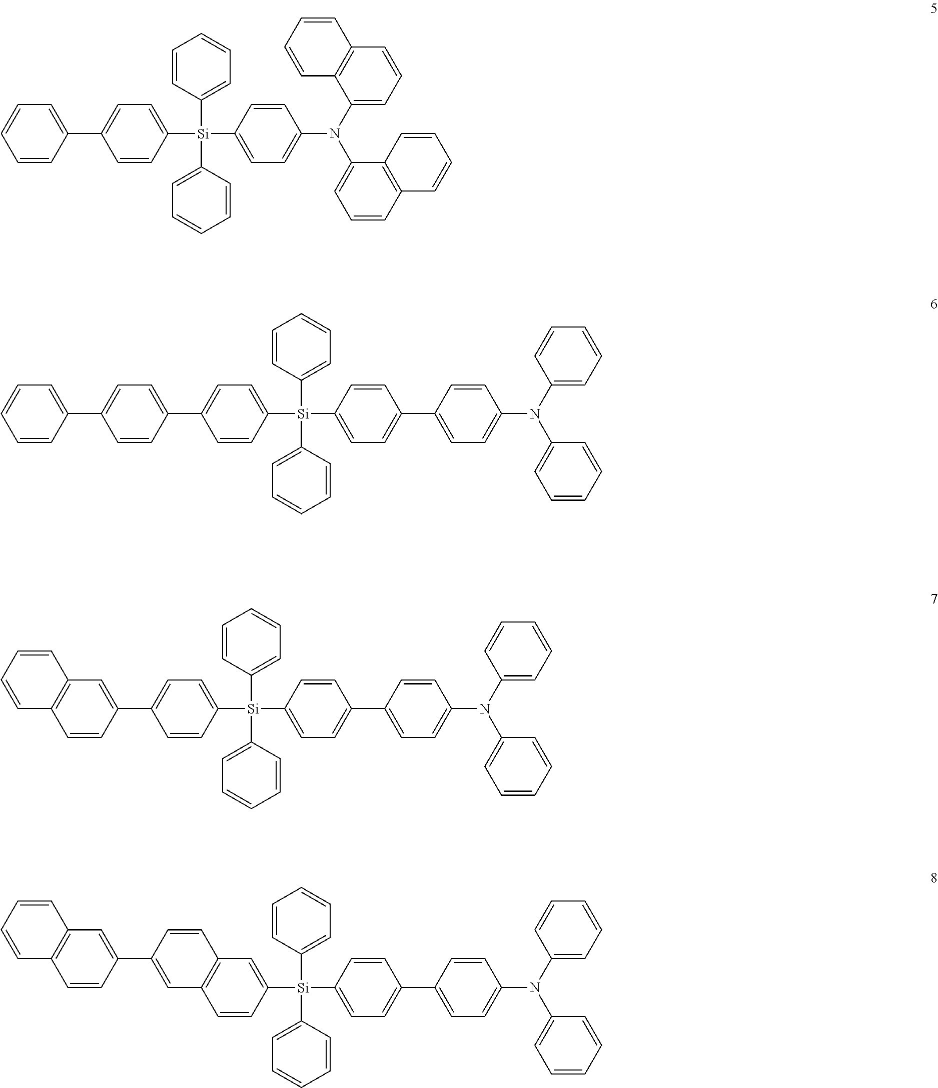 [SMILES: c1ccc(-c2ccc([Si](c3ccccc3)(c3ccccc3)c3ccc(N(c4cccc5ccccc45)c4cccc5ccccc45)cc3)cc2)cc1 ; c1ccc(-c2ccc(-c3ccc([Si](c4ccccc4)(c4ccccc4)c4ccc(-c5ccc(N(c6ccccc6)c6ccccc6)cc5)cc4)cc3)cc2)cc1 ; c1ccc(N(c2ccccc2)c2ccc(-c3ccc([Si](c4ccccc4)(c4ccccc4)c4ccc(-c5ccc6ccccc6c5)cc4)cc3)cc2)cc1 ; c1ccc(N(c2ccccc2)c2ccc(-c3ccc([Si](c4ccccc4)(c4ccccc4)c4ccc5cc(-c6ccc7ccccc7c6)ccc5c4)cc3)cc2)cc1]

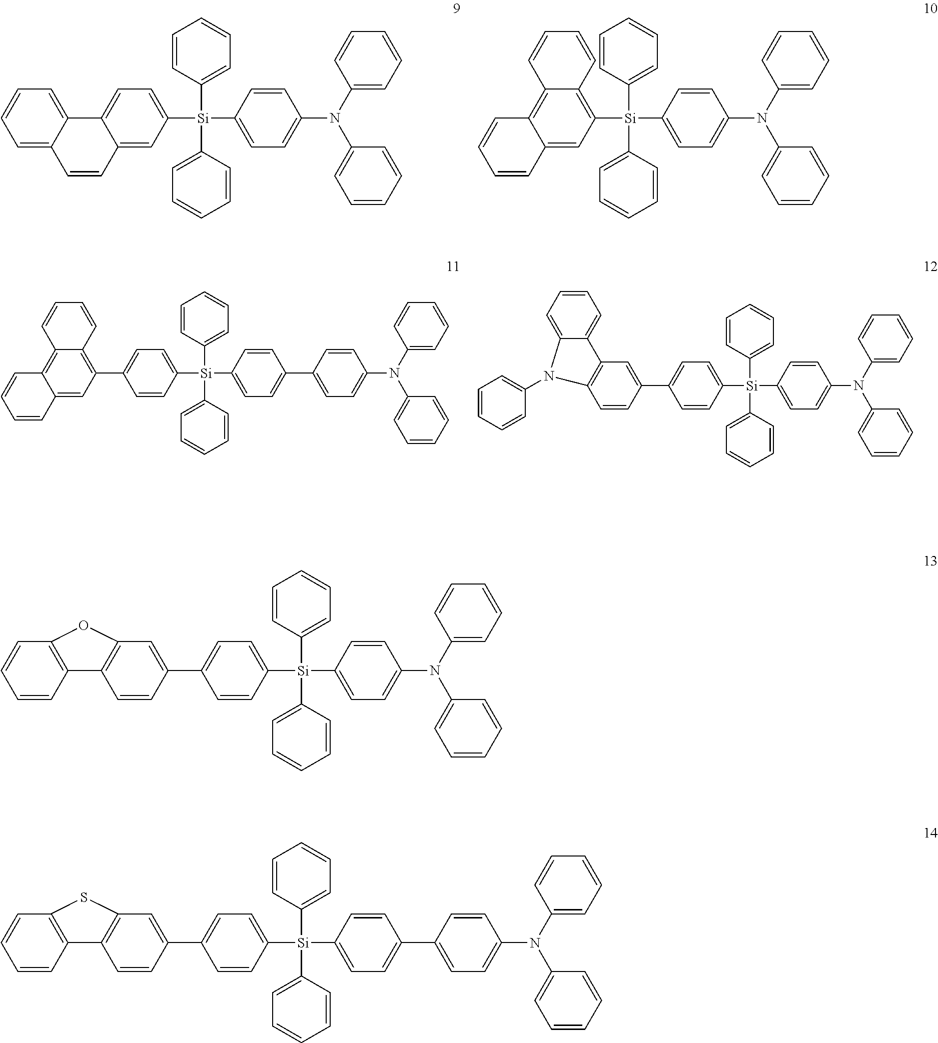

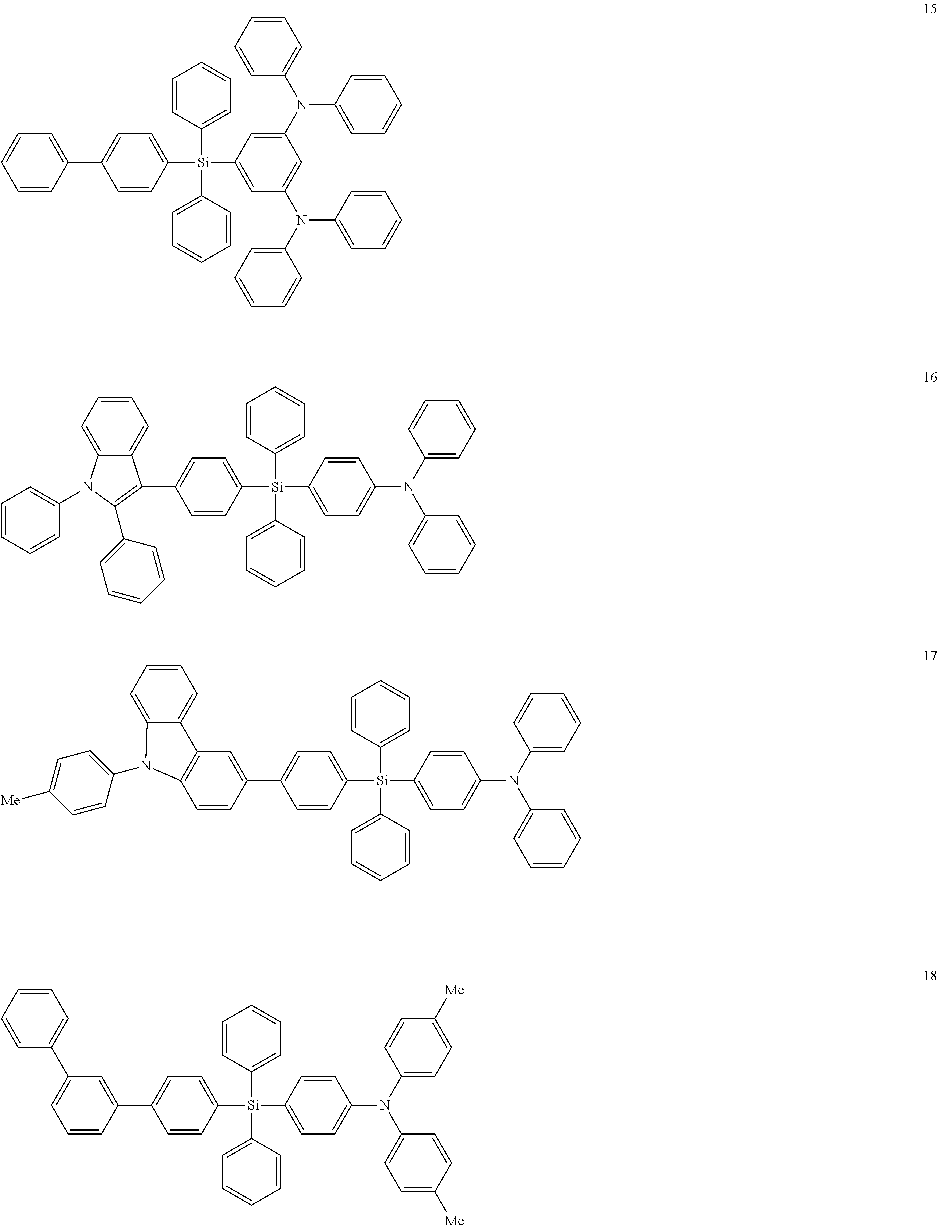 [SMILES: c1ccc(-c2ccc([Si](c3ccccc3)(c3ccccc3)c3cc(N(c4ccccc4)c4ccccc4)cc(N(c4ccccc4)c4ccccc4)c3)cc2)cc1 ; c1ccc(-c2c(-c3ccc([Si](c4ccccc4)(c4ccccc4)c4ccc(N(c5ccccc5)c5ccccc5)cc4)cc3)c3ccccc3n2-c2ccccc2)cc1 ; Cc1ccc(-n2c3ccccc3c3cc(-c4ccc([Si](c5ccccc5)(c5ccccc5)c5ccc(N(c6ccccc6)c6ccccc6)cc5)cc4)ccc32)cc1 ; Cc1ccc(N(c2ccc(C)cc2)c2ccc([Si](c3ccccc3)(c3ccccc3)c3ccc(-c4cccc(-c5ccccc5)c4)cc3)cc2)cc1]

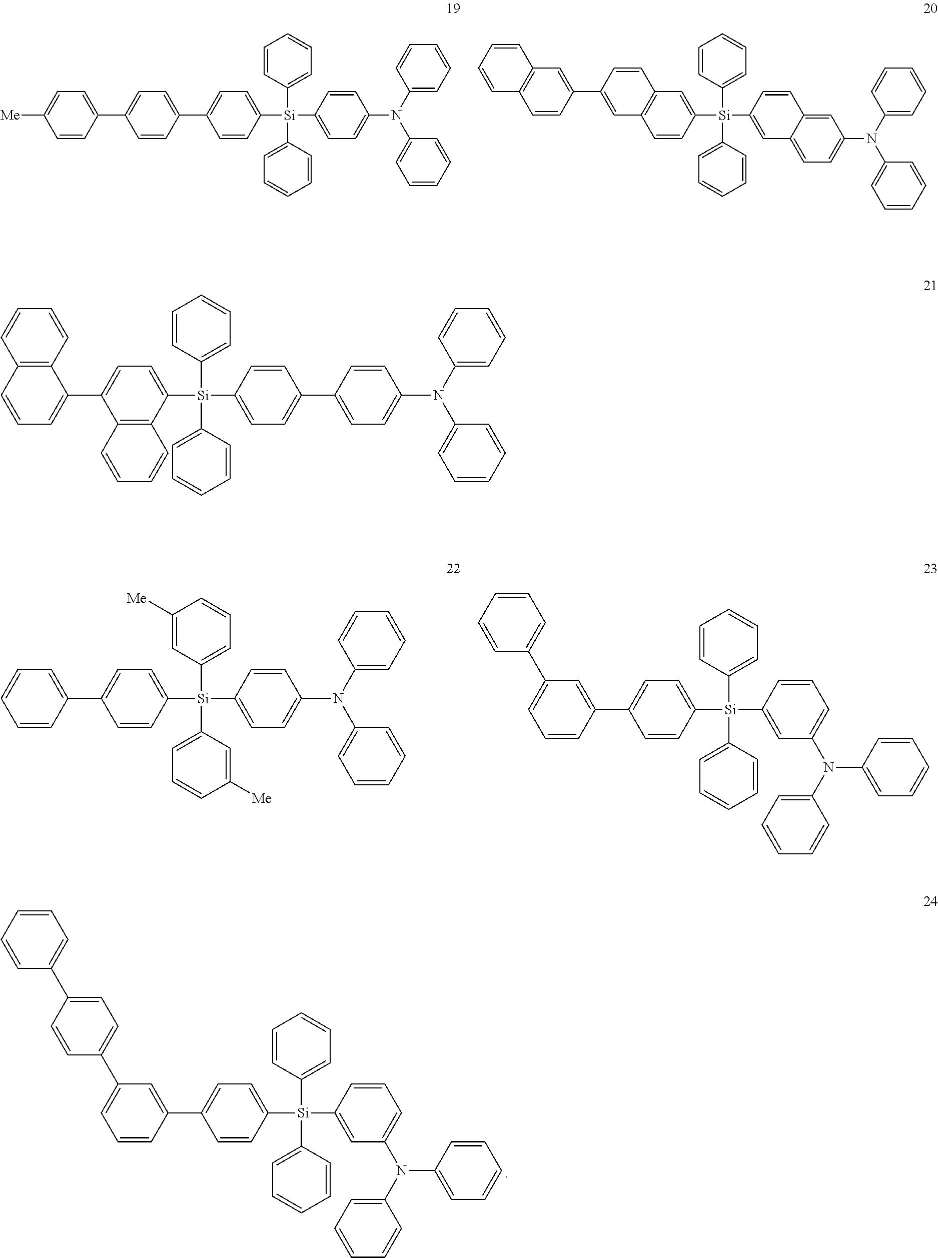

By using the silane compound in an organic EL device, the emission efficiency or the life of the organic EL device may be improved further.

The present disclosure also provides an organic EL device including the silane compound in a layer of stacked layers disposed between an emission layer and an anode in consideration of the above-described defects.

The present disclosure also provides an organic EL device including the silane compound in an emission layer in consideration of the above-described defects.

By including the silane compound in the layer of stacking layers disposed between an emission layer and an anode or the emission layer, the emission efficiency or the life of the organic EL device may be improved further.

As described above, the size of four substituents combined with a silicon atom is defined so as to satisfy a certain relation in the silane compound, and the silane compound is used in the organic EL device, thereby improving the emission efficiency and the life of the organic EL device further.

### BRIEF DESCRIPTION OF THE DRAWINGS

Features will become apparent to those of skill in the art by describing in detail exemplary embodiments with reference to the attached drawings in which:

FIG. 1 is an illustration explaining a silane compound according to an embodiment;

FIG. 2 is a schematic diagram illustrating an organic EL device according to an embodiment;

FIG. 3 is a schematic diagram illustrating an organic EL device manufactured by using a material for an organic EL device according to an embodiment; and

FIG. 4 is a diagram explaining occupied positions of the HOMO and the LUMO of a silane compound.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present.

The Molecular Design of Silane Compound

The molecular orbital of an organic molecule is found be to a factor of the deterioration of an organic molecule in an organic EL device. Various organic molecules used in an organic EL device may include various substituents in the skeleton thereof. When a HOMO and a LUMO are present at the same time in the same molecule, electrons may be transported near a portion having low electron tolerance, while holes may be transported near a portion having low hole tolerance. Thus, the deterioration of the organic molecule may occur during driving an organic EL device, and the driving life of the device may be decreased.

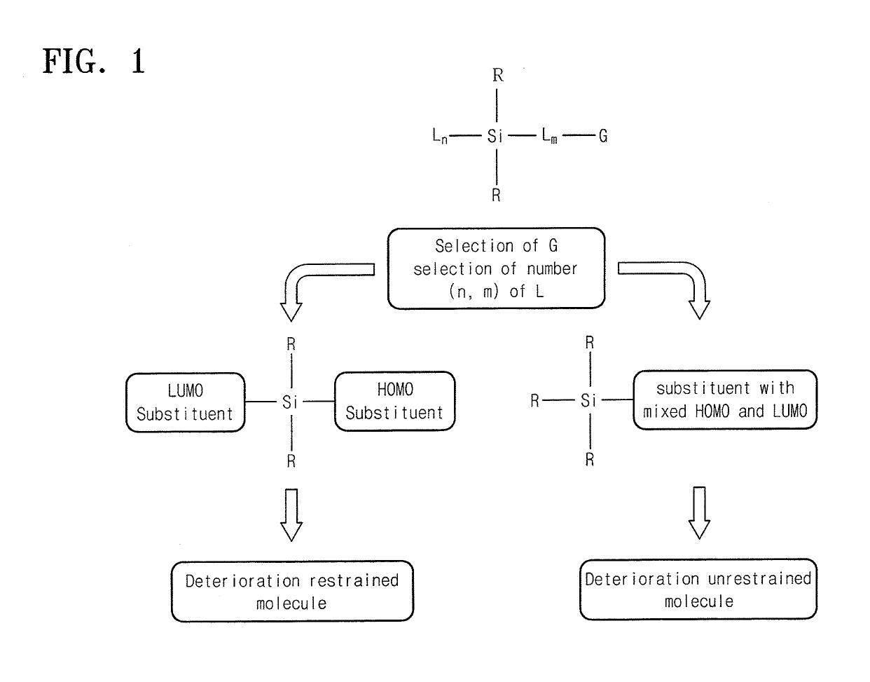

On the basis of the above-described points, and further on the separation technique of the HOMO and the LUMO of the organic molecule, the molecular design concept of a silane compound according to an embodiment will be explained in brief referring to FIG. 1. FIG. 1 is a diagram for explaining a silane compound according to an embodiment.

The silane compound may be a molecule including a silicon atom as shown in the upper part of FIG. 1. The silane compound may be an organic silicon compound substituted with a substituent having charge transporting properties. In FIG. 1, substituent L represents a substituent having charge transporting properties, and R represents a substituent having a minor contribution to the HOMO or the LUMO.

In the silane compound according to an embodiment, even though the same kind of substituents L are substituted with respect to the silicon atom, the number (n, m) of the substituent L, and substituent G of the substituent L are selected so as to satisfy a certain relation. As shown in FIG. 1, by selecting the number (n, m) of the substituent L or the substituent G appropriately, the separation of a substituent in which the HOMO is distributed and a substituent in which the LUMO is distributed, may be provided. Thus, the holes may be transported in the substituent in which the HOMO is distributed, and the electrons may be transported in the substituent in which the LUMO is distributed. The deterioration of the molecules during the driving of the device may be restrained. By using such molecules, the life or the emission efficiency of an organic EL device may be improved.

In the case that the selection of the number (n, m) of the substituent L or the substituent G is inappropriate as illustrated in FIG. 1, the HOMO and the LUMO of the organic molecule may not be separated, and a substituent in which the HOMO and the LUMO are mixed may be present. As a result, the deterioration of the organic molecule may proceed further, and the driving life of a device may be decreased.

A silane compound according to an embodiment designed on the basis of the above-described design concept will be described in detail.

The Silane Compound

An organic EL material according to an embodiment may be a silane compound represented by the following Formula 1:

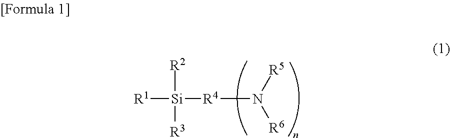

Each of R¹ to R⁶ is independently a monovalent or a divalent group derived from an aromatic hydrocarbon or a heteroaromatic ring having 5 to 30 carbon atoms, R¹ to R⁶ being unsubstituted or substituted with one or more alkyl groups having at most 12 carbon atoms. A carbon number of R¹ is greater than a carbon number of R⁴ by at least 4. A carbon number of R² and R³ is at most 12. A carbon number of R⁵ and R⁶ is at most 18. n is an integer from 1 to 3. The conditions of the following (1) to (3) are satisfied,

(1) with respect to any of R¹ to R⁶ that is substituted with one or more alkyl groups, the number alkyl groups does not exceed the number of hydrogen atoms of the monovalent or divalent group of R¹ to R⁶,

(2) with respect to any one of R¹ to R⁶ that is substituted with one or more alkyl groups, the carbon number of the one of R¹ to R⁶ is obtained by subtracting a carbon number of the one or more alkyl groups, and

(3) the monovalent group or the divalent group is not generated from the substituted alkyl group of R¹ to R⁶.

The silane compound according to an embodiment satisfies the above conditions of (1) to (3) and includes the above-described substituents R¹ to R⁶. The size of the four kinds of substituents combined with the silicon atom may be controlled to a certain size, and the localization of the HOMO and the LUMO in different substituents may be possible. For example, the substituent R⁴ and a substituent introduced in the substituent R₄ and defined as an amine skeleton (—NR⁵R⁶)ₙ may be a substituent that provides localization of the HOMO, and the substituent R¹ may be a substituent that provides localization of the LUMO.

If the carbon number of R¹ were to be less than the carbon number of R⁴+5, and if the carbon number of R² and R³ were to exceed 12, or the carbon number of R⁵ and R⁶ were to exceed 18, the localization of the HOMO and the LUMO in different substituents might not be attained. Thus, the long life or the high efficiency of the organic EL device might not be realized.

In addition, even though R¹ is represented as a substituent that provides localization of the LUMO, the position of the substituent R¹ may be the position of R² or the position of R³ in the above Formula 1, because the position of the substituents R¹ to R³ are equivalent in consideration of a tetrahedron structure with the silicon as a center.

In the above Formula 1, the alkyl group introduced in R¹ to R⁶ may have a straight chain, a branched chain, or a ring shape, having at most 12 carbon atoms. The alkyl group may be, for example, a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, a cyclopropyl group, a cyclobutyl group, a cyclopentyl group, a cyclohexyl group, a 4-methylcyclohexyl group, a 1-adamantyl group, a 2-adamantyl group, a 1-norbonyl group, a 2-norbonyl group, etc.

In the above Formula 1, R¹ to R⁶ may be, for example, a monovalent or a divalent substituent derived from an aromatic or heteroaromatic group such as benzene, naphthalene, anthracene, phenanthrene, carbazole, dibenzofuran, dibenzothiophene, indole, benzofuran, benzothiophene, or an aromatic hydrocarbon produced by connecting one or more of these to each other.

For example, R¹ may be (R⁷)ᵢ where R⁷ is benzene or naphthalene. R⁴ may be a (R⁷)ᵢ where R⁷ is benzene or naphthalene. i may be greater than j. In the above-described silane compound, the separation of the HOMO and the LUMO may be provided more distinctly.

In addition, in the above Formula 1, R¹, R², and R³ may be the same.

As examples, the silane compound represented by the above Formula 1 may include Compound 1 to Compound 24 in the following structures:

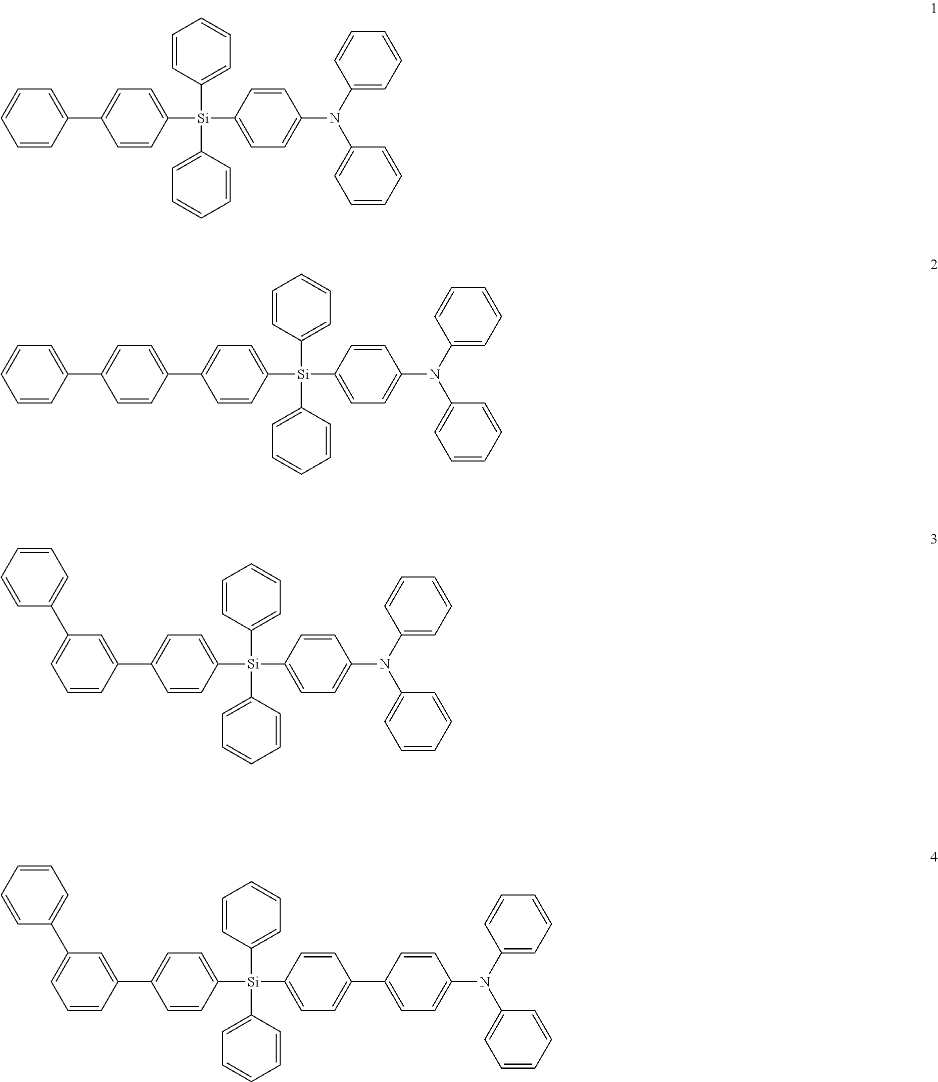 [SMILES: c1ccc(-c2ccc([Si](c3ccccc3)(c3ccccc3)c3ccc(N(c4ccccc4)c4ccccc4)cc3)cc2)cc1 ; c1ccc(-c2ccc(-c3ccc([Si](c4ccccc4)(c4ccccc4)c4ccc(N(c5ccccc5)c5ccccc5)cc4)cc3)cc2)cc1 ; c1ccc(-c2cccc(-c3ccc([Si](c4ccccc4)(c4ccccc4)c4ccc(N(c5ccccc5)c5ccccc5)cc4)cc3)c2)cc1 ; c1ccc(-c2cccc(-c3ccc([Si](c4ccccc4)(c4ccccc4)c4ccc(-c5ccc(N(c6ccccc6)c6ccccc6)cc5)cc4)cc3)c2)cc1]

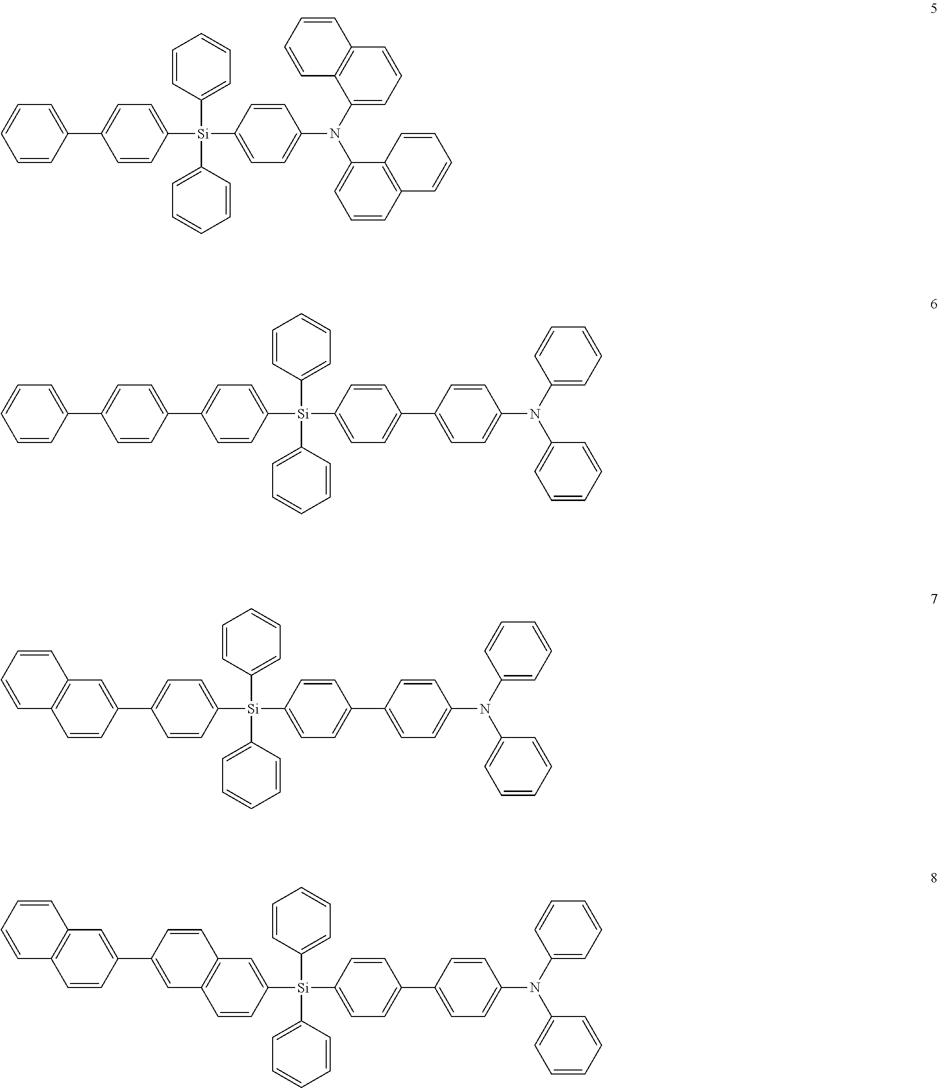 [SMILES: c1ccc(-c2ccc([Si](c3ccccc3)(c3ccccc3)c3ccc(N(c4cccc5ccccc45)c4cccc5ccccc45)cc3)cc2)cc1 ; c1ccc(-c2ccc(-c3ccc([Si](c4ccccc4)(c4ccccc4)c4ccc(-c5ccc(N(c6ccccc6)c6ccccc6)cc5)cc4)cc3)cc2)cc1 ; c1ccc(N(c2ccccc2)c2ccc(-c3ccc([Si](c4ccccc4)(c4ccccc4)c4ccc(-c5ccc6ccccc6c5)cc4)cc3)cc2)cc1 ; c1ccc(N(c2ccccc2)c2ccc(-c3ccc([Si](c4ccccc4)(c4ccccc4)c4ccc5cc(-c6ccc7ccccc7c6)ccc5c4)cc3)cc2)cc1]

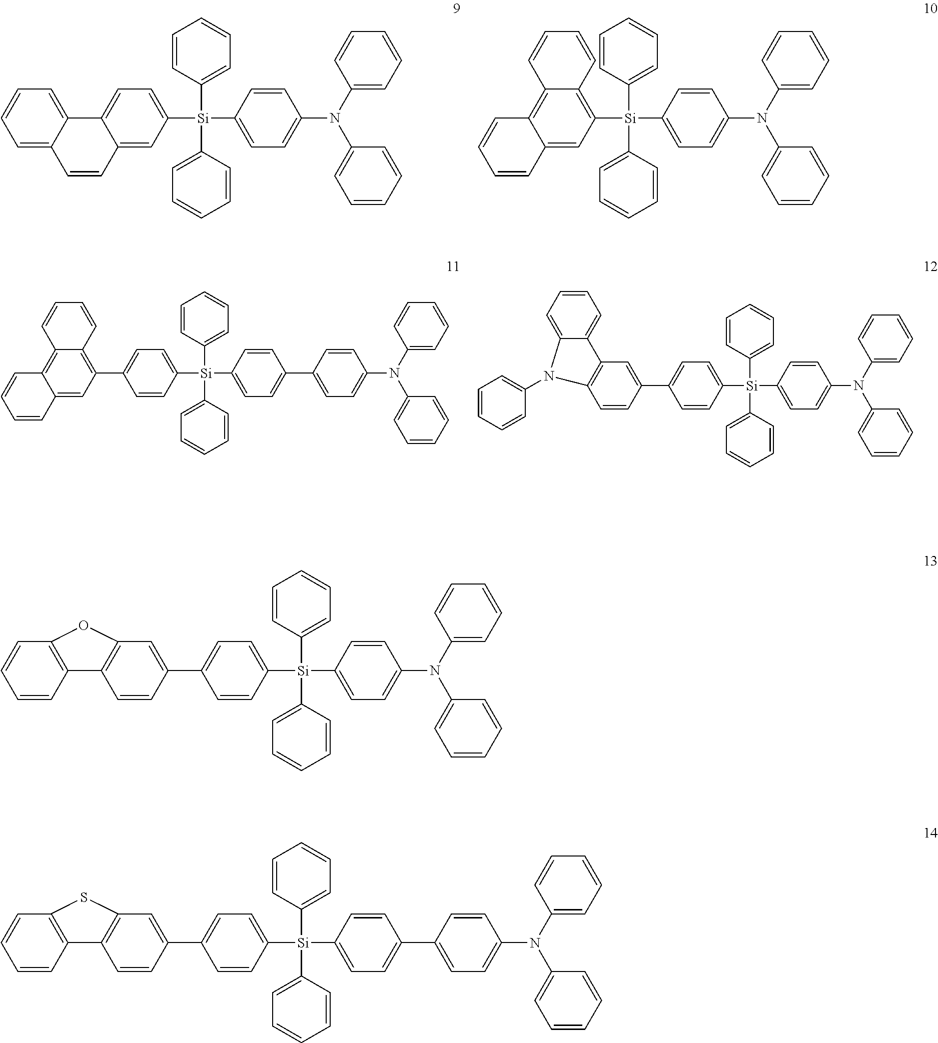

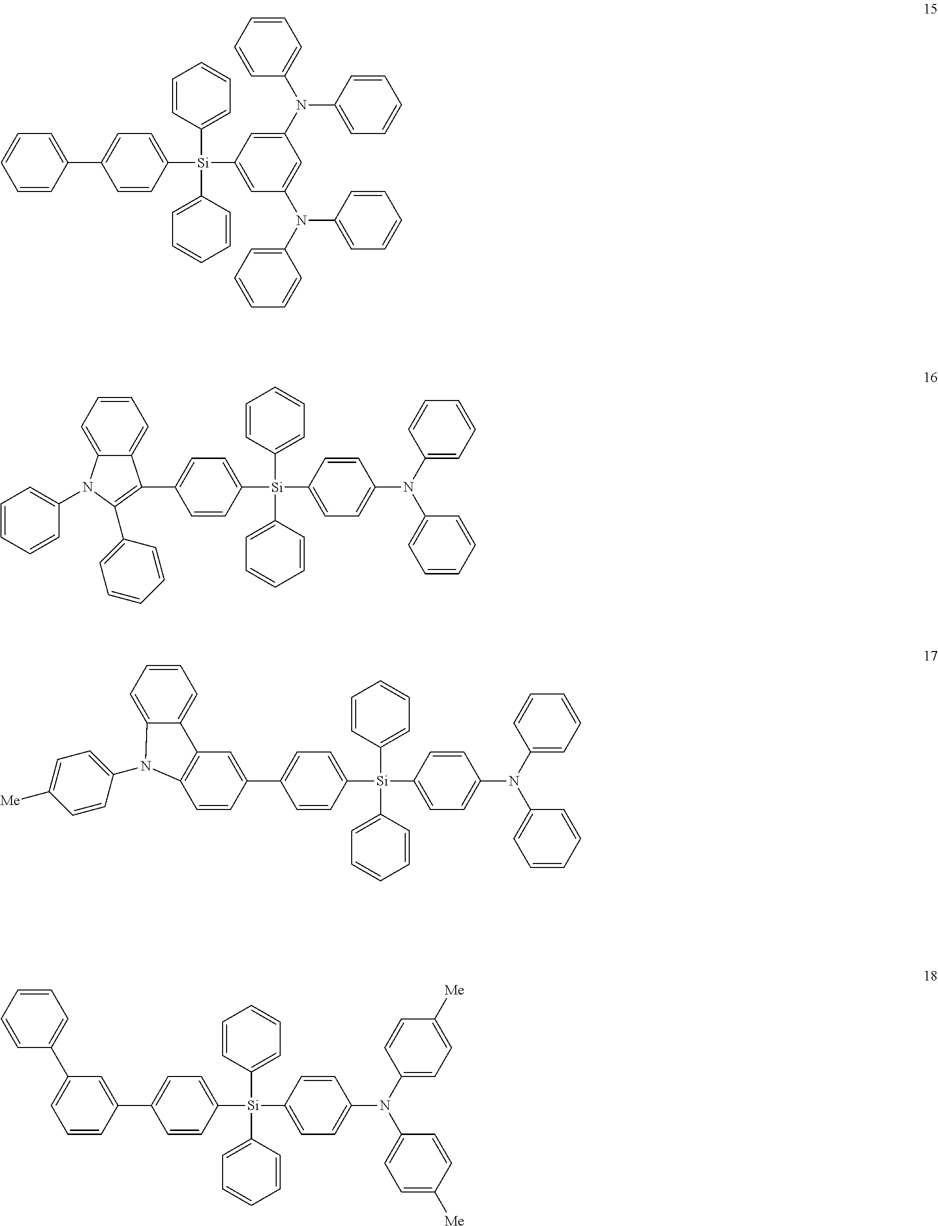 [SMILES: c1ccc(-c2ccc([Si](c3ccccc3)(c3ccccc3)c3cc(N(c4ccccc4)c4ccccc4)cc(N(c4ccccc4)c4ccccc4)c3)cc2)cc1 ; c1ccc(-c2c(-c3ccc([Si](c4ccccc4)(c4ccccc4)c4ccc(N(c5ccccc5)c5ccccc5)cc4)cc3)c3ccccc3n2-c2ccccc2)cc1 ; Cc1ccc(-n2c3ccccc3c3cc(-c4ccc([Si](c5ccccc5)(c5ccccc5)c5ccc(N(c6ccccc6)c6ccccc6)cc5)cc4)ccc32)cc1 ; Cc1ccc(N(c2ccc(C)cc2)c2ccc([Si](c3ccccc3)(c3ccccc3)c3ccc(-c4cccc(-c5ccccc5)c4)cc3)cc2)cc1]

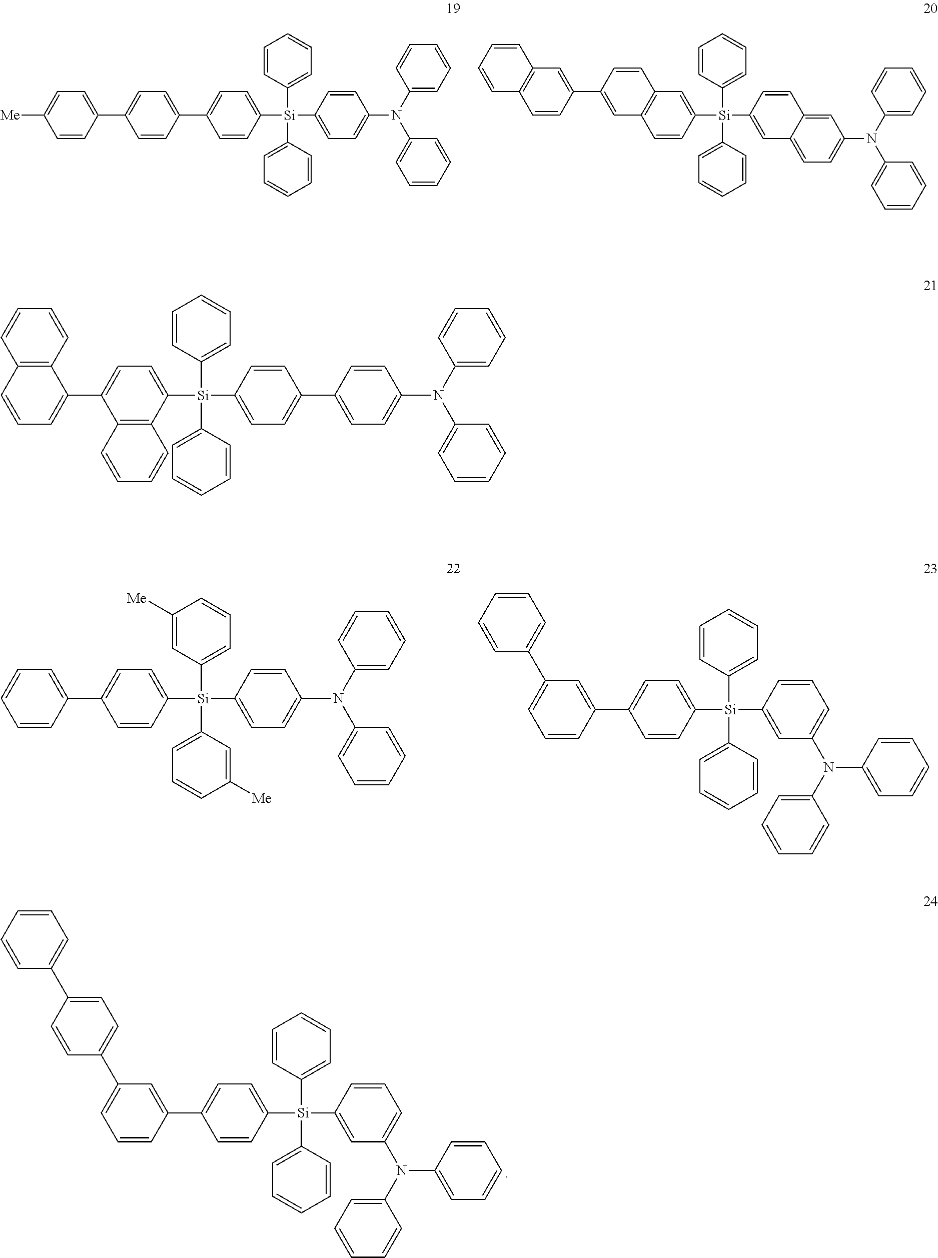

The silane compounds described above may be used as a material for an organic EL device. In the silane compound represented by Formula 1, the size of four substituents combined with a silicon atom is defined so as to satisfy a certain relation, and the localization of the HOMO and the LUMO in different substituents may be attained. Thus, the silane compound according to an embodiment may be used as a material for an organic EL device. For example, the silane compound may be used as a material of a hole transport layer adjacent to an emission layer. By using the silane compound according to an embodiment as the material of the hole transport layer, the electron tolerance of the hole transport layer may be improved, the deterioration of a hole transport material due to the invasion of electrons into the hole transport layer may be restrained, and the increase of life of an organic EL device may be realized. In addition, by using the silane compound according to an embodiment as the material of the hole transport layer, the emission efficiency of the organic EL device may be improved further.

In other implementations, the silane compound according to this embodiment may be used as a material of a hole injection layer. When using the silane compound according to this embodiment as the material of the hole injection layer, the deterioration of the hole injection layer due to electrons may be also restrained. Thus, the long life of the organic EL device may be realized as in the case of using the silane compound as the material of the hole transport layer.

As described above, the silane compound according to an embodiment has been described in detail.

Synthetic Method of Silane Compound

Hereinafter, a synthetic method of a silane compound according to an embodiment will be explained in brief.

The silane compound according to an embodiment may be synthesized by a generalized method as shown in the following scheme.

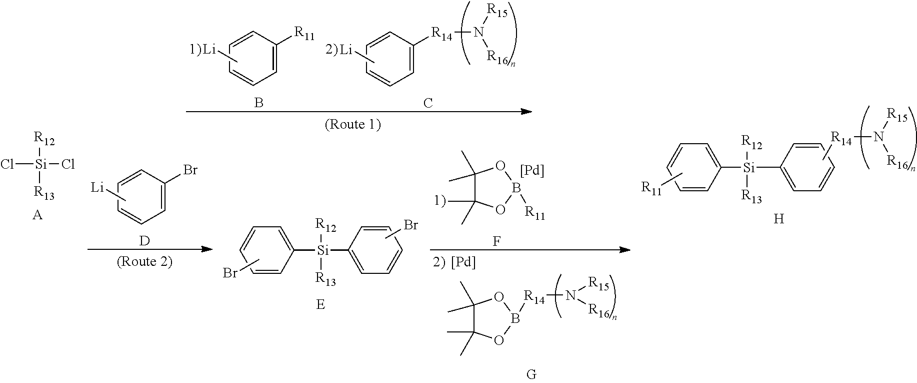

In the case of synthesizing a silane compound according to this embodiment, i.e.,

Compound H, having a typical structure as shown in the above scheme may be synthesized as follows.

According to the first method, as shown in the above Route 1, Compound H may be produced by conducting continuous reaction of an organic lithium compound with respect to dichlorosilane A. According to this method, the number of reaction process may be decreased. However this method may be sometimes inapplicable due to the stability of the organic lithium compound.

According to the second method, as shown in the above Route 2, a reaction of a halogenated organic lithium compound D with dichlorosilane A may be conducted to isolate a dibromo intermediate E. Then, Compound H may be produced by conducting reactions of Compound F and Compound G one by one by using, for example, a Suzuki coupling reaction. According to the second method, the number of reaction process may be increased, but the product may be more stably produced.

Organic EL Device Using Silane Compound

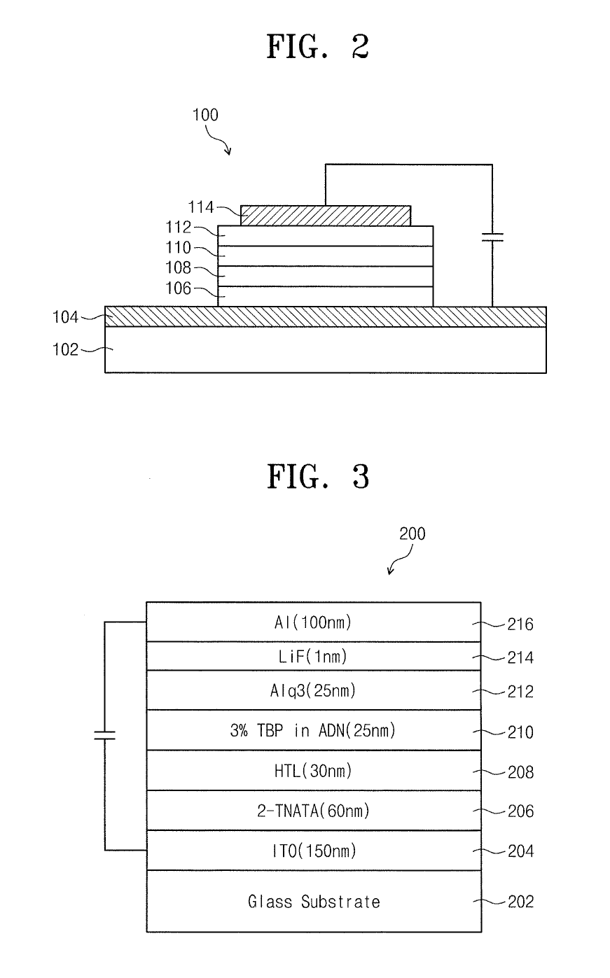

Referring to FIG. 2, an organic EL device using a silane compound according to an embodiment will be described in brief. FIG. 2 illustrates a schematic diagram depicting an organic EL device according to an embodiment.

The organic EL device according to this embodiment has, for example, a structure illustrated in FIG. 2.

An organic EL device 100 shown in FIG. 2 is a schematic cross-sectional view, in which the silane compound according to an embodiment is used as a material for an organic EL device. The organic EL device 100 may include a glass substrate 102, an anode 104 disposed on the glass substrate 102, a hole injection layer 106 disposed on the anode 104, a hole transport layer 108 disposed on the hole injection layer 106, an emission layer 110 disposed on the hole transport layer 108, an electron transport layer 112 disposed on the emission layer 110, and a cathode 114 disposed on the electron transport layer 112. The electron transport layer 112 may also function as an electron injection layer.

By using the silane compound according to an embodiment in at least one material of a material for a hole injection layer and a material for a hole transport layer for respectively forming the hole injection layer 106 and the hole transport layer 108 of the organic EL device, an organic EL device having long life and high efficiency may be manufactured.

In the device structure of the organic EL device 100 in FIG. 2, suitable materials for an organic EL device may be used with respect to the anode 104, the emission layer 110, the electron transport layer 112 and the cathode 114.

In addition, as described above, the silane compound according to an embodiment may have electron tolerance. Accordingly, the silane compound may be used as the material of the hole transport layer or the material of the hole injection layer in an organic EL device. In other implementations, the silane compound according to an embodiment may be used as a host material in an emission layer.

As described above, an embodiment of an organic EL device using the silane compound according to an embodiment has been described in brief with reference to FIG. 2.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details of the silane compound, the organic EL device, and the synthesis methods described in the Examples and Comparative Examples.

### EXAMPLES

### Synthesis of Compound 6

The following chemical reaction corresponds to a synthetic process of Compound 6 as the silane compound according to an embodiment. The following synthetic process is a synthetic process corresponding to the above-described Route 2. A dibromo compound J in the following chemical reaction is a known material, and various synthetic methods are known (for example, Liu et al., Adv. Funct. Mater. 2012, 22, 2830, etc.).

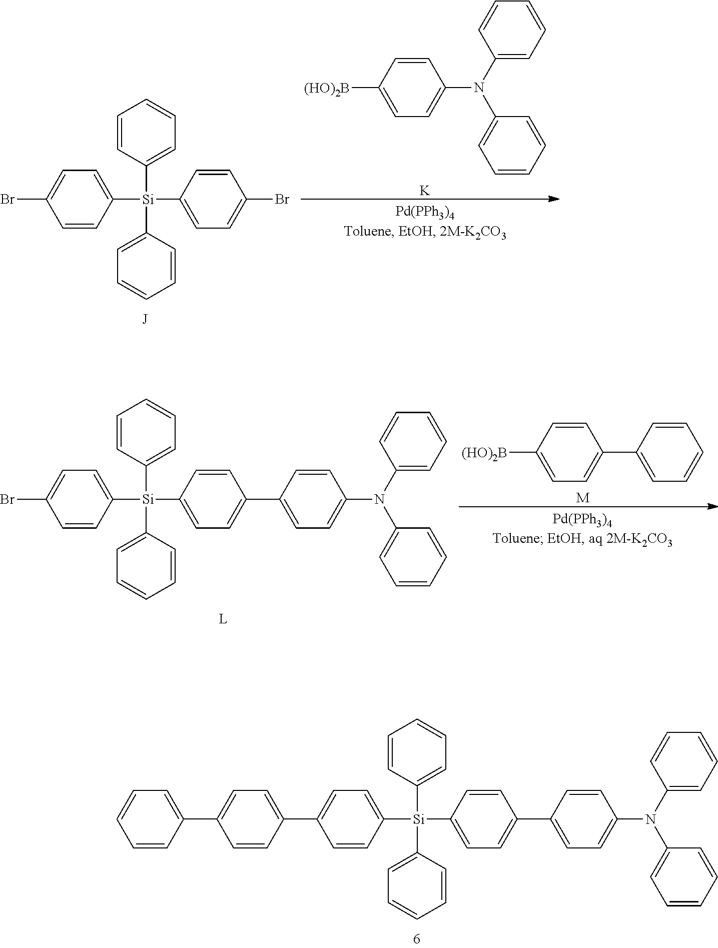

(Synthesis of Bromoamine L)

Dibromodiphenylsilane J (5.54 g, 11.2 mmol), boronic acid K (3.24 g, 11.2 mmol), and tetrakistriphenylphosphine palladium(0) (388 mg, 0.336 mmol) were added in toluene (200 mL), ethanol (50 mL) and 2 M potassium carbonate aqueous solution (100 mL), followed by degassing under a reduced pressure, and heating and stirring at 80° C. for 5 hours under an argon atmosphere. An organic layer was extracted from the reactant and was washed with water and saturated saline. The organic layer was dried with anhydrous magnesium sulfate and concentrated to produce a residue. The residue thus obtained was separated by column chromatography to produce bromoamine L as a nearly white powder (4.06 g, 6.16 mmol, 55%).

[Synthesis of Compound 6]

Bromoamine L (2.24 g, 3.40 mmol), boronic acid M (0.808 g, 4.08 mmol), and tetrakistriphenylphosphine palladium(0) (196 mg, 0.170 mmol) were added in toluene (100 mL), ethanol (20 mL) and 2 M potassium carbonate aqueous solution (50 mL), followed by degassing under a reduced pressure, and heating and stirring at 100° C. for 8 hours under an argon atmosphere. An organic layer was extracted from the reactant and washed with water and saturated saline. The organic layer was dried with anhydrous magnesium sulfate and concentrated to produce a residue. The residue thus obtained was separated by column chromatography to produce Compound 6 as a nearly white powder (1.94 g, 2.65 mmol, 78%).

[Synthesis of Compound 7]

The same procedure as the above synthetic method of Compound 6 was conducted except for using a naphthyl group as the substituent of the boronic acid M instead of a biphenyl group to produce Compound 7.

[Synthesis of Compound 14]

The same procedure as the above synthetic method of Compound 6 was conducted except for using a benzothiophene group as the substituent of the boronic acid M instead of a biphenyl group to produce Compound 14.

[Manufacture of Organic EL Device]

### Example 1

The manufacture of an organic EL device according to an embodiment was conducted according to the following steps by a vacuum deposition method. First, an ITO glass substrate patterned and washed previously was surface treated using ozone (O₃). The thickness of the ITO layer was 150 nm. Immediately after the ozone treatment, a layer was formed using 4,4′,4″-tris (N,N-(2-naphthyl)amino)triphenylamine (2-TNATA, film thickness of 60 nm) on the ITO layer.

Then, a layer was formed (30 nm) using the above Compound 6 as a hole transporting material to form a hole transport layer (HTL). Then, a layer was formed using 9,10-di(2-naphthyl)anthracene (β-ADN) doped with 3% 2,5,8,11-tetra-t-butylphenylene (TBP) by a co-deposition (layer thickness of 25 nm).

After that, a layer was formed using tris(8-quinolato)aluminum (Alq3) as an electron transporting material (layer thickness of 25 nm), and lithium fluoride (LiF) as an electron injection material (layer thickness of 1.0 nm) and aluminum as a cathode (layer thickness of 100 nm) were stacked one by one to manufacture an organic EL device 200.

### Example 2

The same procedure described in Example 1 was performed except for using Compound 7 instead of Compound 6 to manufacture an organic EL device.

### Example 3

The same procedure described in Example 1 was performed except for using Compound 14 instead of Compound 6 to manufacture an organic EL device.

### Comparative Examples 1 and 2

As Comparative Examples 1 and 2, organic EL devices were manufactured by performing the same procedure described in Example 1 and using Comparative Compound c1 and Comparative Compound c2 having the following structures as compounds composing the hole transporting material of an organic EL device. Comparative Compound c1 used in Comparative Example 1 corresponded to a compound represented by the above Formula 1 in which the carbon number of substituent R¹ and the carbon number of substituent R⁴ were the same and was different from the silane compound according to an embodiment. In addition, Comparative Compound c2 used in Comparative Example 2 was a commonly used hole transporting material.

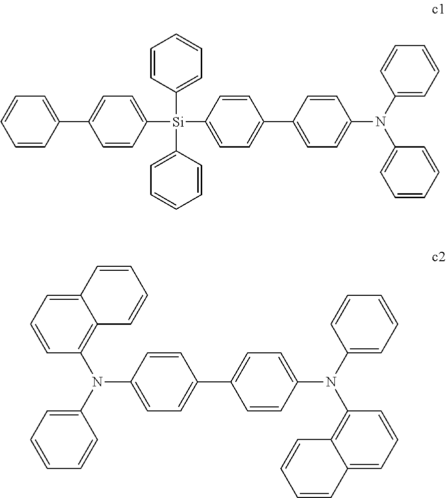 [SMILES: c1ccc(-c2ccc([Si](c3ccccc3)(c3ccccc3)c3ccc(-c4ccc(N(c5ccccc5)c5ccccc5)cc4)cc3)cc2)cc1 ; c1ccc(N(c2ccc(-c3ccc(N(c4ccccc4)c4cccc5ccccc45)cc3)cc2)c2cccc3ccccc23)cc1]

The schematic diagram of the organic EL device 200 manufactured in Example 1, Example 2, Comparative Example 1 and Comparative Example 2 is illustrated in FIG. 3. The organic EL device 200 thus manufactured included a glass substrate 202, an anode 204 disposed on the glass substrate 202, a hole injection layer 206 disposed on the anode 204, a hole transport layer 208 disposed on the hole injection layer 206, an emission layer 210 disposed on the hole transport layer 208, an electron transport layer 212 and an electron injection layer 214 disposed on the emission layer 210, and a cathode 216 disposed on the electron injection layer 214.

The performance of the organic EL device 200 manufactured in Example 1, Example 2, Comparative Example 1 and Comparative Example 2 is illustrated in the following Table 1. For the evaluation of the electric field emission properties, a C9920-11 luminance alignment measuring apparatus of HAMAMATSU Photonics was used. In the following Table 1, the values were measured at current density of 10 mA/cm² and half life of 1,000 cd/m².

TABLE 1

| | Hole | | Emission | Life |
|---|---|---|---|---|
| | transport | Voltage | efficiency | LT50 |
| | material | (V) | (cd/A) | (hr) |
| Example 1 | Compound 6 | 8.2 | 6.1 | 3,700 |
| Example 2 | Compound 7 | 8.3 | 6.2 | 2,800 |
| Example 3 | Compound 14 | 7.9 | 5.9 | 3,000 |
| Comparative | Comparative | 8.5 | 5.9 | 900 |
| Example 1 | Compound 1 | | | |
| Comparative | Comparative | 8.1 | 5.3 | 1,200 |
| Example 2 | Compound 2 | | | |

Referring to the above Table 1, the improvement of the emission efficiency and the marked improvement of the driving life while maintaining the driving voltage were recognized for the devices including the silane compounds of Compounds 6 and 7 according to an embodiment when compared to those according to Comparative Example 1. In addition, the lowering of the driving voltage and the marked improvement of the driving life while maintaining the emission efficiency were recognized for the device including the silane compound of Compound 14 according to an embodiment when compared to those according to Comparative Example 1. When the devices according to Examples 1 to 3 were compared to that of Comparative Example 2 (that is, in the case that a common hole transport material was stacked), the improvement of the emission efficiency was recognized, and the improvement of the driving voltage was recognized in Example 3. Accordingly, the driving life of the device may be markedly improved while maintaining the emission efficiency by using the silane compound according to an embodiment.

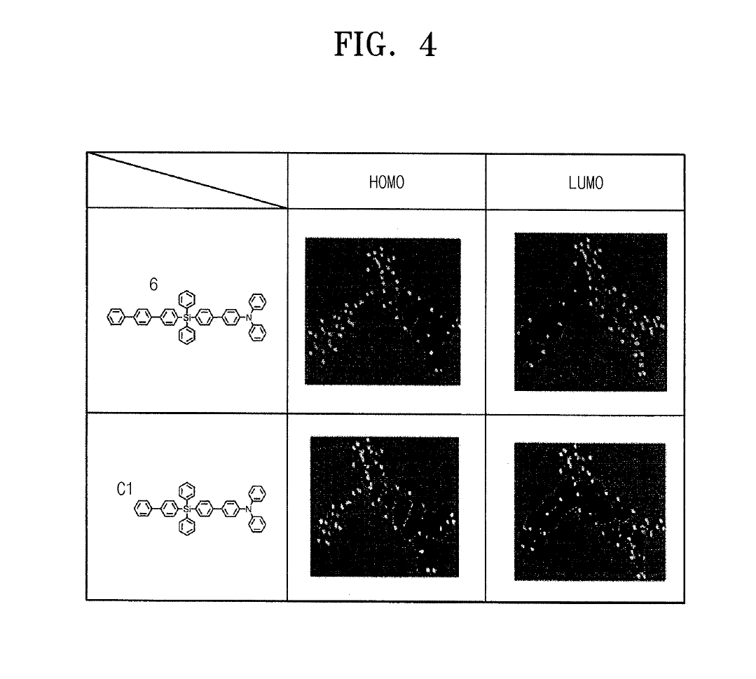

FIG. 4 illustrates a diagram for explaining occupied positions of the HOMO and the LUMO of a silane compound. As shown in FIG. 4, Comparative Compound c1 includes one less phenyl group when compared to the silane compound of Compound 6 according to an embodiment, and the remaining part has the same molecular structure. However, the HOMO-LUMO positions of a proton are quite different as shown in FIG. 4 when obtaining molecular orbitals using Gaussian 09, which is a common application, and performing structure optimization calculation: B3LYP/6-31G(d) and TD-DFT calculation: B3LYP/6-31G(d). That is, in the silane compound of Compound 6, the HOMO and the LUMO are positioned at different substituents, however, in Comparative Compound c1, the mixing of the HOMO and the LUMO may be recognized. Due to the different features, the difference of device properties as shown in Table 1 may be obtained.

In the above-described embodiments, the silane compound was used as the hole transport material of the organic EL device. However, the silane compound may be used in other emission devices or emission apparatuses other than the organic EL device. In addition, the organic EL devices illustrated in FIGS. 2 and 3 may be used in an organic EL display of a passive matrix driving type, or in an organic EL display of an active matrix driving type.

By way of summation and review, an organic EL device may include a plurality of layers having different properties such as an emission layer and a layer for transporting carriers such as holes or electrons to the emission layer. Various compounds have been examined as a material used in an organic EL device to improve the emission properties and the life of the organic EL device. For example, an organic Si compound having a triphenylene skeleton may be used as a phosphorescent host compound in an emission layer of an emission display.

However, an organic EL device manufactured by using a phosphorescent host material may have insufficient emission properties or life. A material for manufacturing an organic EL device with higher efficiency and longer life is desirable.

Embodiments provide a silane compound that may have increased emission efficiency and life in consideration of the above-described defects, and an organic EL device using the silane compound.

Embodiments provide an organic EL device including the silane compound in a layer of stacking layers disposed between an emission layer and an anode.

Embodiments provide an organic EL device including the silane compound in an emission layer in consideration of the above-described defects.

By including the silane compound in the layer of stacking layers disposed between an emission layer and an anode or in the emission layer, the emission efficiency or the life of the organic EL device may be improved further.

According to embodiments, the size of four substituents combined with a silicon atom is defined so as to satisfy a certain relation in the silane compound. The silane compound is used in the organic EL device, thereby further improving the emission efficiency and the life of the organic EL device.

Example embodiments have been disclosed herein, and although specific terms are employed, they are used and are to be interpreted in a generic and descriptive sense only and not for purpose of limitation. Accordingly, it will be understood by those of skill in the art that various changes in form and details may be made without departing from the spirit and scope thereof as set forth in the following claims.

What is claimed is:

1. A silane compound represented by following Formula 1: 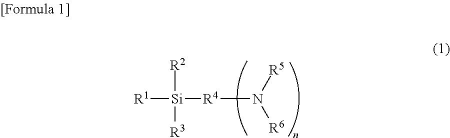
where each of R¹ to R⁶ is independently a monovalent or a divalent group derived from an aromatic hydrocarbon or a heteroaromatic ring having 5 to 30 carbon atoms, R¹ to R⁶ being unsubstituted or substituted with one or more alkyl groups having at most 12 carbon atoms,
a carbon number of R¹ is greater than a carbon number of R⁴ by at least 4,
a carbon number of R² and R³ is at most 12,
a carbon number of R⁵ and R⁶ is at most 18,
n is an integer from 1 to 3, and
conditions of the following (1) to (3) are satisfied,
(1) with respect to any of R¹ to R⁶ that is substituted with one or more alkyl groups, the number alkyl groups does not exceed the number of hydrogen atoms of the monovalent or divalent group of R¹ to R⁶,
(2) with respect to any one of R¹ to R⁶ that is substituted with one or more alkyl groups, the carbon number of the one of R¹ to R⁶ is obtained by subtracting a carbon number of the one or more alkyl groups, and
(3) the monovalent group or the divalent group is not generated from the substituted alkyl group of R¹ to R⁶.

2. The silane compound as claimed in claim 1, wherein R¹ to R⁶ are independently derived from benzene, naphthalene, anthracene, phenanthrene, carbazole, dibenzofuran, dibenzothiophene, indole, benzofuran, benzothiophene, or an aromatic or heteroaromatic group produced by connecting one or more of these to each other.

3. The silane compound as claimed in claim 2, wherein:
R¹ is (R⁷)ᵢ, where R⁷ is a benzene or naphthylene moiety,
R⁴ is (R⁷)ⱼ, where R⁷ is a benzene or naphthylene moiety, and
i>j.

4. The silane compound as claimed in claim 1, wherein R¹, R², and R³ are the same.

5. The silane compound as claimed in claim 1, wherein the silane compound is at least one selected from the following Compounds 1 to 24:

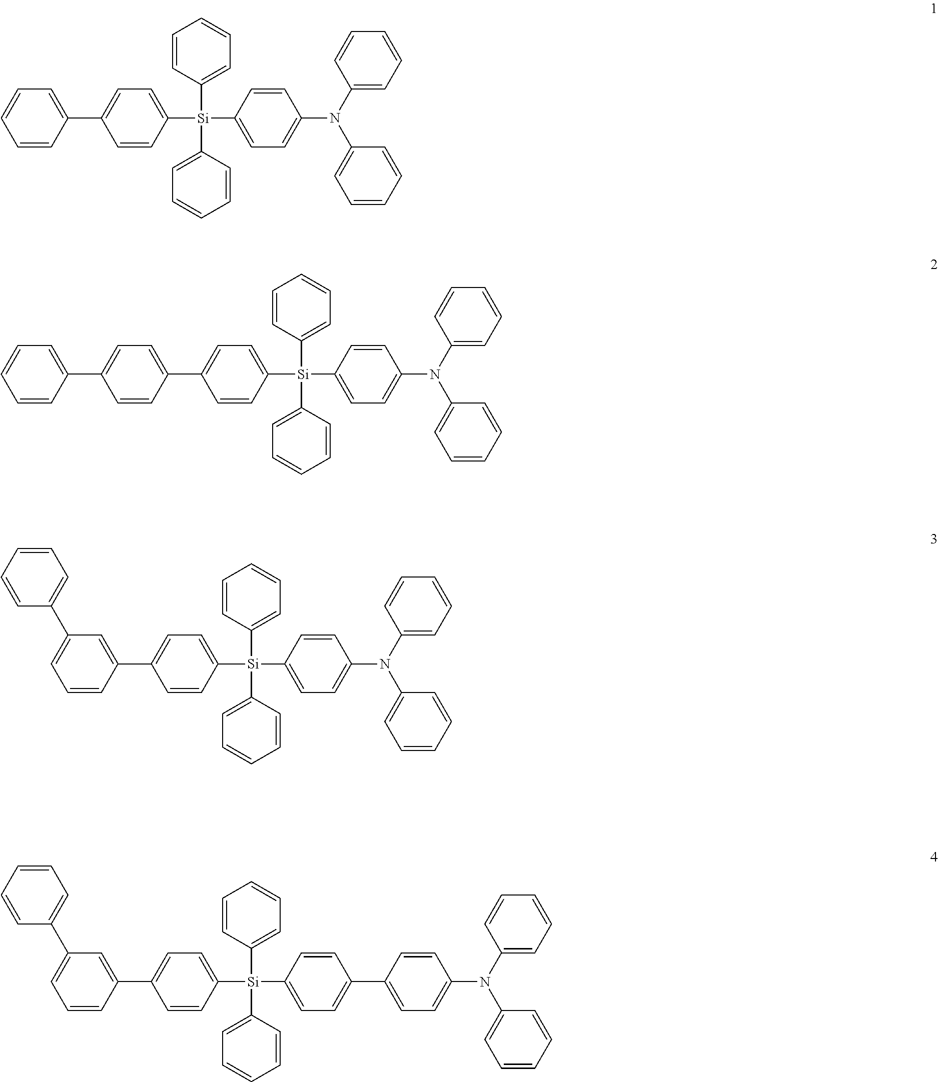 [SMILES: c1ccc(-c2ccc([Si](c3ccccc3)(c3ccccc3)c3ccc(N(c4ccccc4)c4ccccc4)cc3)cc2)cc1 ; c1ccc(-c2ccc(-c3ccc([Si](c4ccccc4)(c4ccccc4)c4ccc(N(c5ccccc5)c5ccccc5)cc4)cc3)cc2)cc1 ; c1ccc(-c2cccc(-c3ccc([Si](c4ccccc4)(c4ccccc4)c4ccc(N(c5ccccc5)c5ccccc5)cc4)cc3)c2)cc1 ; c1ccc(-c2cccc(-c3ccc([Si](c4ccccc4)(c4ccccc4)c4ccc(-c5ccc(N(c6ccccc6)c6ccccc6)cc5)cc4)cc3)c2)cc1]

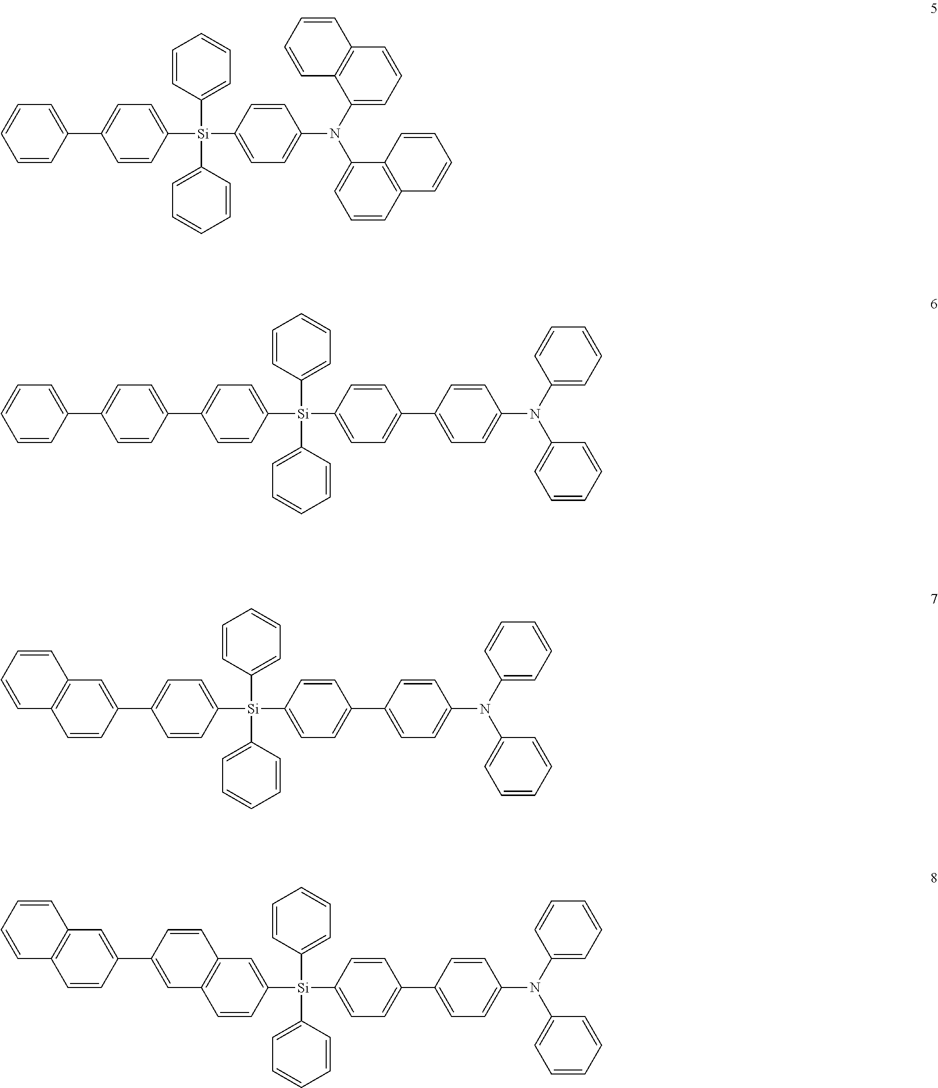 [SMILES: c1ccc(-c2ccc([Si](c3ccccc3)(c3ccccc3)c3ccc(N(c4cccc5ccccc45)c4cccc5ccccc45)cc3)cc2)cc1 ; c1ccc(-c2ccc(-c3ccc([Si](c4ccccc4)(c4ccccc4)c4ccc(-c5ccc(N(c6ccccc6)c6ccccc6)cc5)cc4)cc3)cc2)cc1 ; c1ccc(N(c2ccccc2)c2ccc(-c3ccc([Si](c4ccccc4)(c4ccccc4)c4ccc(-c5ccc6ccccc6c5)cc4)cc3)cc2)cc1 ; c1ccc(N(c2ccccc2)c2ccc(-c3ccc([Si](c4ccccc4)(c4ccccc4)c4ccc5cc(-c6ccc7ccccc7c6)ccc5c4)cc3)cc2)cc1]

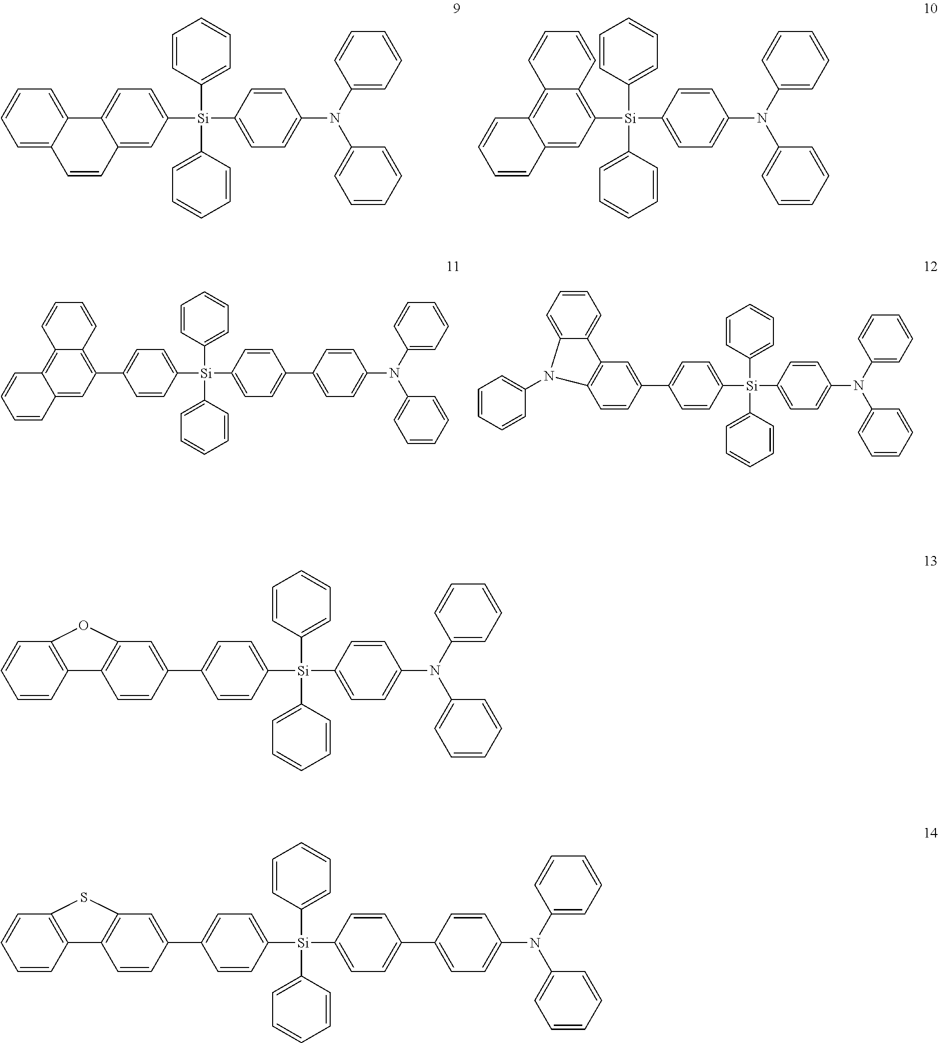

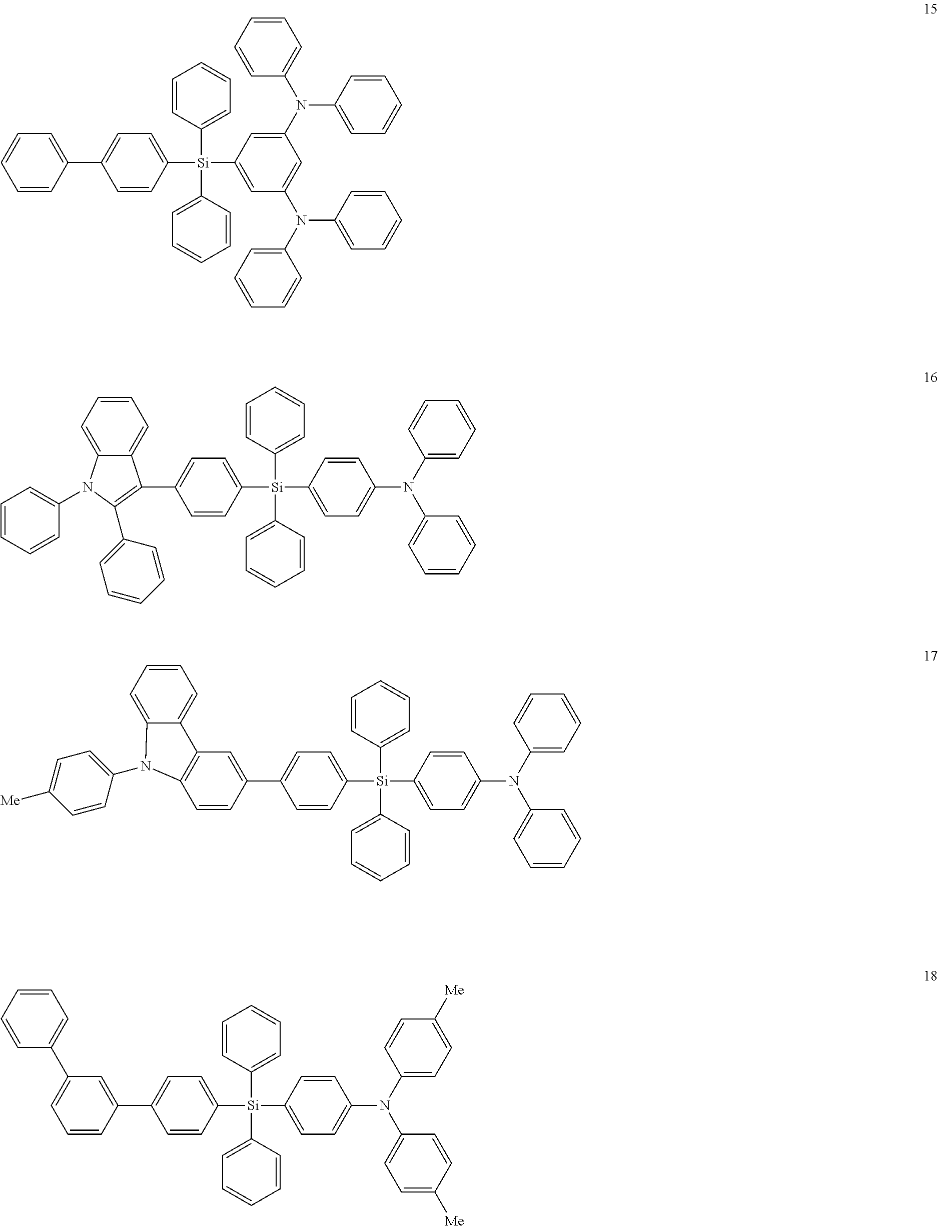 [SMILES: c1ccc(-c2ccc([Si](c3ccccc3)(c3ccccc3)c3cc(N(c4ccccc4)c4ccccc4)cc(N(c4ccccc4)c4ccccc4)c3)cc2)cc1 ; c1ccc(-c2c(-c3ccc([Si](c4ccccc4)(c4ccccc4)c4ccc(N(c5ccccc5)c5ccccc5)cc4)cc3)c3ccccc3n2-c2ccccc2)cc1 ; Cc1ccc(-n2c3ccccc3c3cc(-c4ccc([Si](c5ccccc5)(c5ccccc5)c5ccc(N(c6ccccc6)c6ccccc6)cc5)cc4)ccc32)cc1 ; Cc1ccc(N(c2ccc(C)cc2)c2ccc([Si](c3ccccc3)(c3ccccc3)c3ccc(-c4cccc(-c5ccccc5)c4)cc3)cc2)cc1]

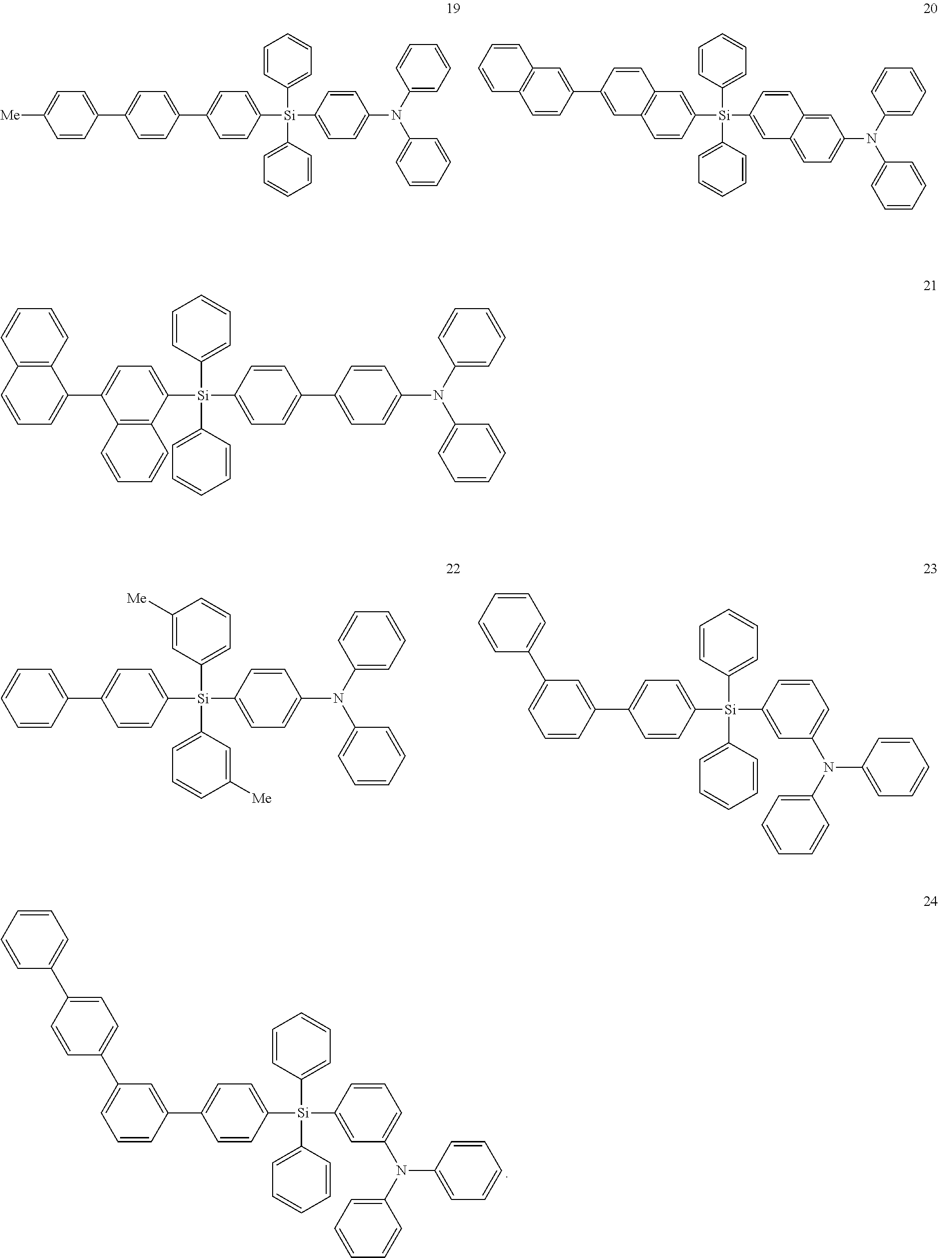

6. An organic electroluminescence (EL) device, comprising a silane compound in at least one layer of a stacked layers disposed between an emission layer and an anode, and the emission layer,
the silane compound being represented by the following Formula 1: 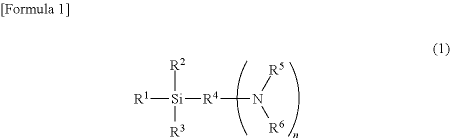
where each of R¹ to R⁶ is independently a monovalent or a divalent group derived from an aromatic hydrocarbon or a heteroaromatic ring having 5 to 30 carbon atoms, R¹ to R⁶ being unsubstituted or substituted with one or more alkyl groups having at most 12 carbon atoms,
a carbon number of R¹ is greater than a carbon number of R⁴ by at least 4,
a carbon number of R² and R³ is at most 12,
a carbon number of R⁵ and R⁶ is at most 18,
n is an integer from 1 to 3, and
conditions of the following (1) to (3) are satisfied,
(1) with respect to any of R¹ to R⁶ that is substituted with one or more alkyl groups, the number alkyl groups does not exceed the number of hydrogen atoms of the monovalent or divalent group of R¹ to R⁶,
(2) with respect to any one of R¹ to R⁶ that is substituted with one or more alkyl groups, the carbon number of the one of R¹ to R⁶ is obtained by subtracting a carbon number of the one or more alkyl groups, and
(3) the monovalent group or the divalent group is not generated from the substituted alkyl group of R¹ to R⁶.

7. The organic EL device as claimed in claim 6, wherein R¹ to R⁶ are independently derived from benzene, naphthalene, anthracene, phenanthrene, carbazole, dibenzofuran, dibenzothiophene, indole, benzofuran, benzothiophene, or an aromatic or heteroaromatic group produced by connecting one or more of these to each other.

8. The organic EL device as claimed in claim 7, wherein:
R¹ is (R⁷)ᵢ, where R⁷ is a benzene or naphthylene moiety,
R⁴ is (R⁷)ⱼ, where R⁷ is a benzene or naphthylene moiety, and
i>j.

9. The organic EL device as claimed in claim 6, wherein R¹, R², and R³ are the same.

10. The organic EL device as claimed in claim 6, wherein the silane compound is at least one selected from the following Compounds 1 to 24: 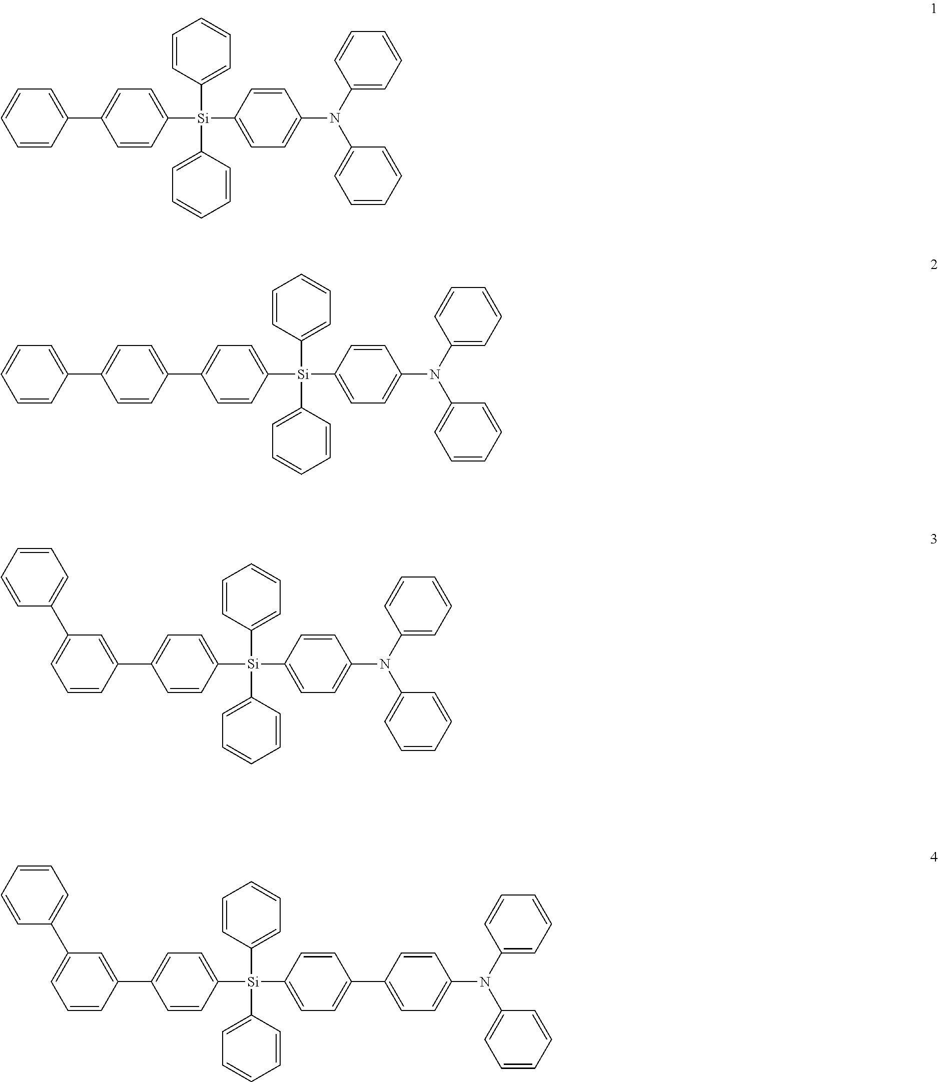 [SMILES: c1ccc(-c2ccc([Si](c3ccccc3)(c3ccccc3)c3ccc(N(c4ccccc4)c4ccccc4)cc3)cc2)cc1 ; c1ccc(-c2ccc(-c3ccc([Si](c4ccccc4)(c4ccccc4)c4ccc(N(c5ccccc5)c5ccccc5)cc4)cc3)cc2)cc1 ; c1ccc(-c2cccc(-c3ccc([Si](c4ccccc4)(c4ccccc4)c4ccc(N(c5ccccc5)c5ccccc5)cc4)cc3)c2)cc1 ; c1ccc(-c2cccc(-c3ccc([Si](c4ccccc4)(c4ccccc4)c4ccc(-c5ccc(N(c6ccccc6)c6ccccc6)cc5)cc4)cc3)c2)cc1] 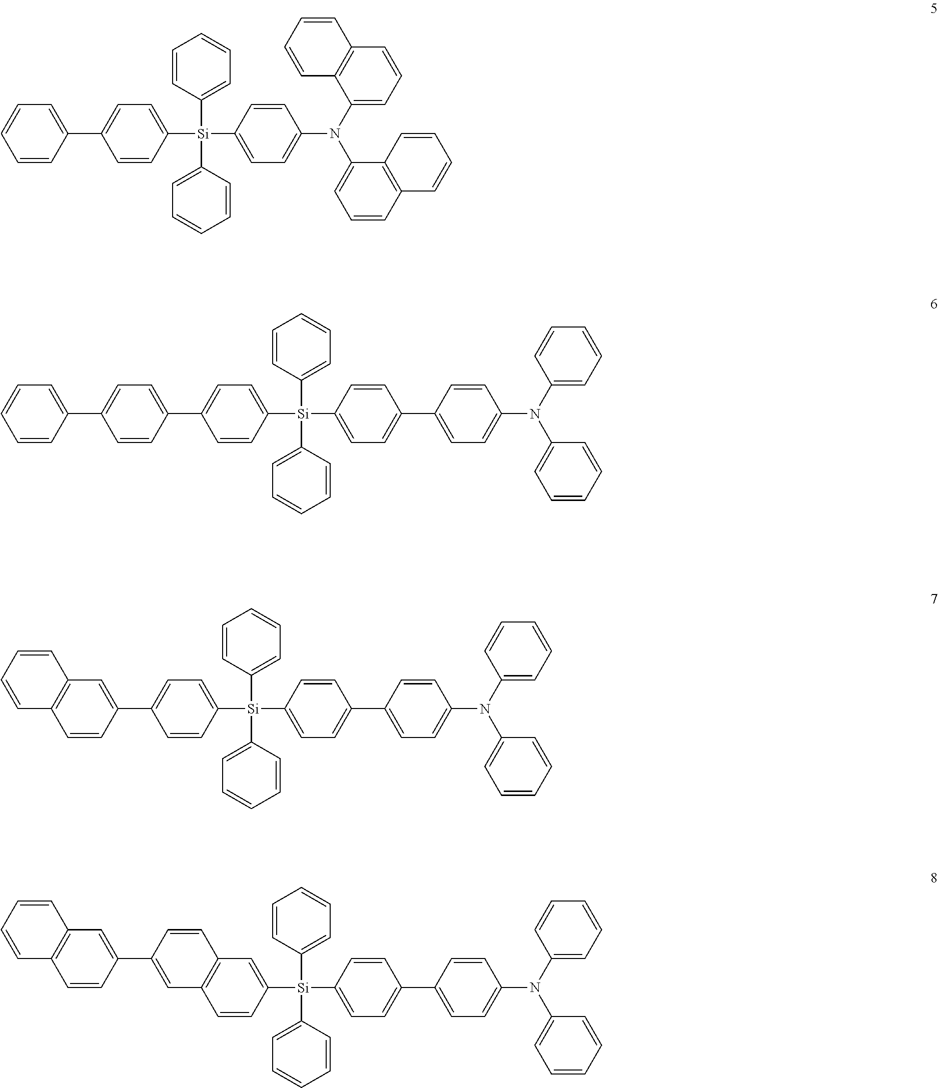 [SMILES: c1ccc(-c2ccc([Si](c3ccccc3)(c3ccccc3)c3ccc(N(c4cccc5ccccc45)c4cccc5ccccc45)cc3)cc2)cc1 ; c1ccc(-c2ccc(-c3ccc([Si](c4ccccc4)(c4ccccc4)c4ccc(-c5ccc(N(c6ccccc6)c6ccccc6)cc5)cc4)cc3)cc2)cc1 ; c1ccc(N(c2ccccc2)c2ccc(-c3ccc([Si](c4ccccc4)(c4ccccc4)c4ccc(-c5ccc6ccccc6c5)cc4)cc3)cc2)cc1 ; c1ccc(N(c2ccccc2)c2ccc(-c3ccc([Si](c4ccccc4)(c4ccccc4)c4ccc5cc(-c6ccc7ccccc7c6)ccc5c4)cc3)cc2)cc1] 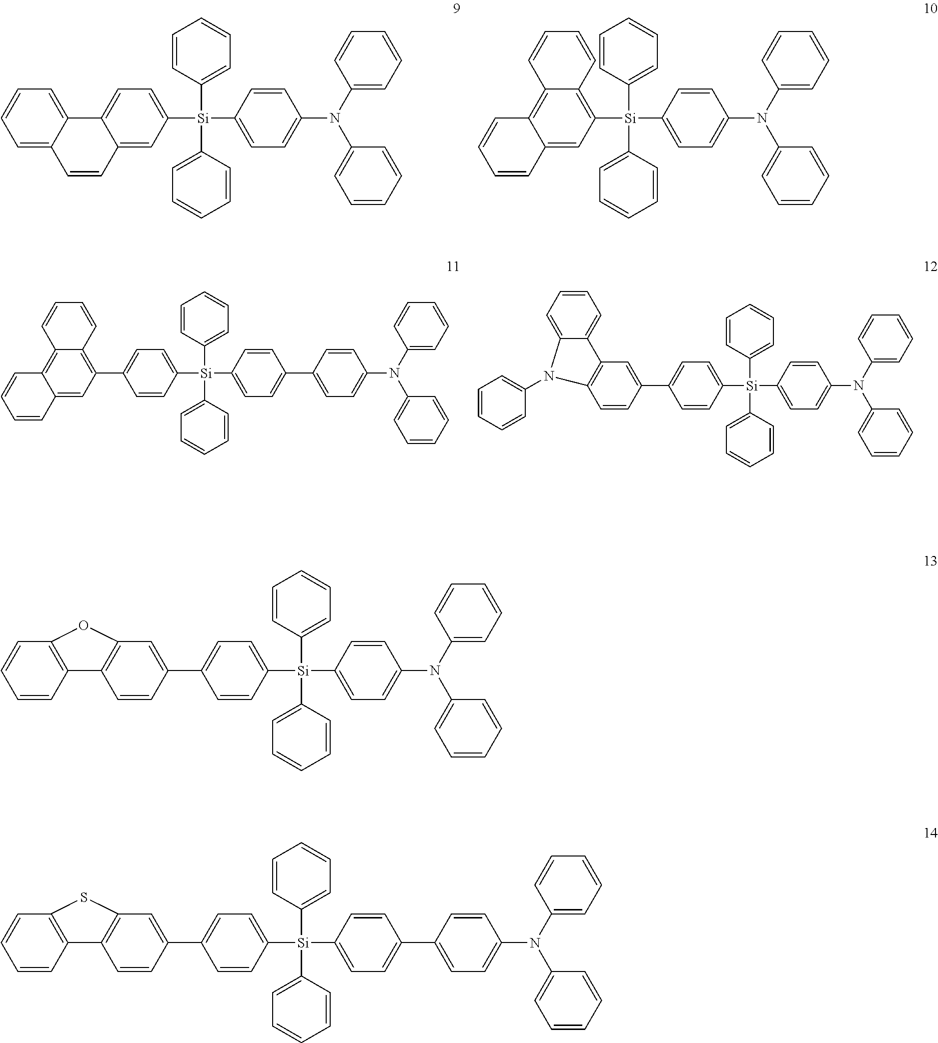 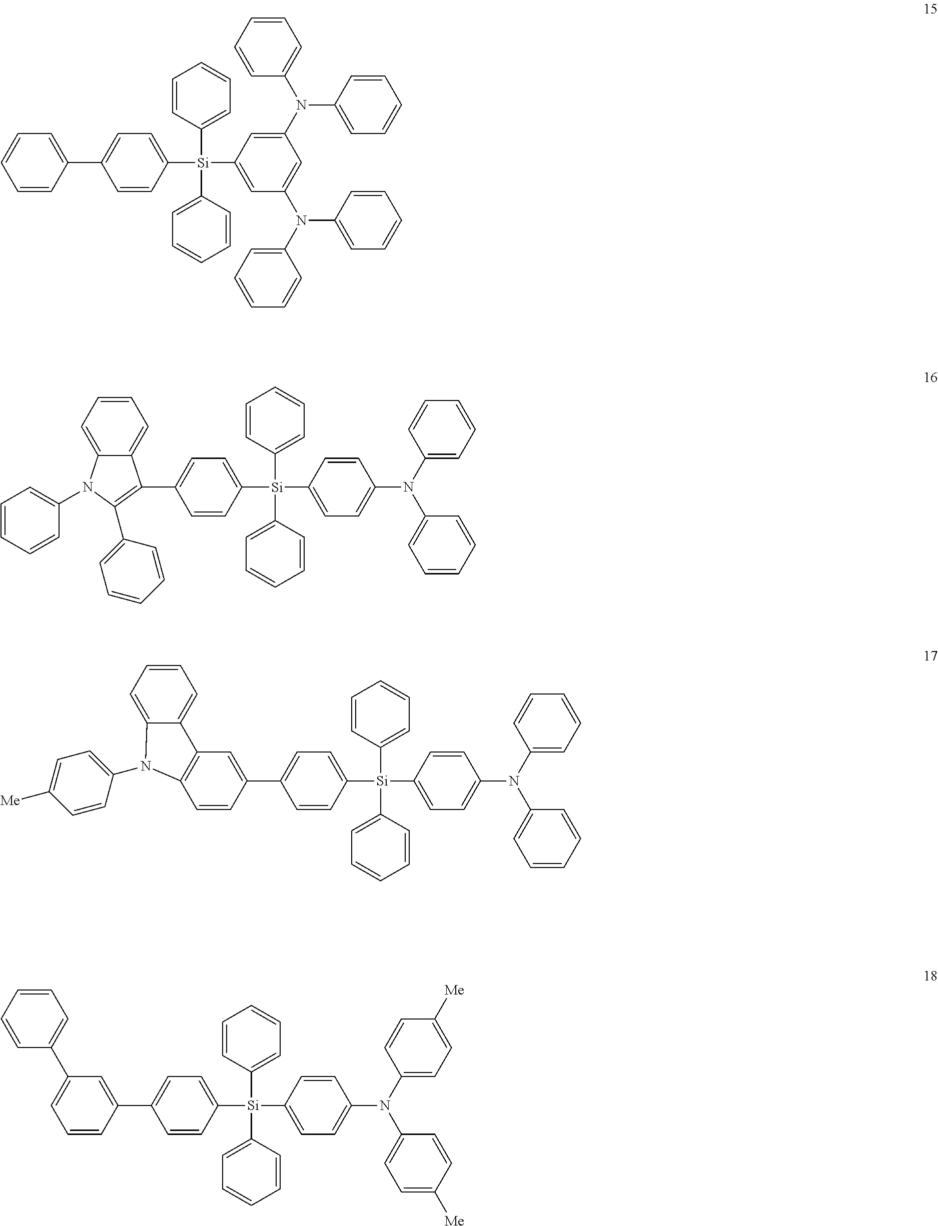 [SMILES: c1ccc(-c2ccc([Si](c3ccccc3)(c3ccccc3)c3cc(N(c4ccccc4)c4ccccc4)cc(N(c4ccccc4)c4ccccc4)c3)cc2)cc1 ; c1ccc(-c2c(-c3ccc([Si](c4ccccc4)(c4ccccc4)c4ccc(N(c5ccccc5)c5ccccc5)cc4)cc3)c3ccccc3n2-c2ccccc2)cc1 ; Cc1ccc(-n2c3ccccc3c3cc(-c4ccc([Si](c5ccccc5)(c5ccccc5)c5ccc(N(c6ccccc6)c6ccccc6)cc5)cc4)ccc32)cc1 ; Cc1ccc(N(c2ccc(C)cc2)c2ccc([Si](c3ccccc3)(c3ccccc3)c3ccc(-c4cccc(-c5ccccc5)c4)cc3)cc2)cc1] [chemical structure]
